(19) United States
(12) Patent Application Publication
(10) Pub. No.: US 2026/0143695 A1
(43) Pub. Date: May 21, 2026

(54) SEMICONDUCTOR MEMORY DEVICE

(71) Applicant: SAMSUNG ELECTRONICS CO., LTD., Suwon-si (KR)

(72) Inventors: Dayoung LEE, Suwon-si (KR); Inyoung LEE, Suwon-si (KR)

(73) Assignee: SAMSUNG ELECTRONICS CO., LTD., Suwon-si (KR)

(21) Appl. No.: 19/391,661

(22) Filed: Nov. 17, 2025

(30) Foreign Application Priority Data
Nov. 19, 2024 (KR) 10-2024-0165605

(51) Int. Cl. H10B 12/00

(52) U.S. Cl. CPC H10B 12/50; H10B 12/33

(57) ABSTRACT

A semiconductor memory device has includes: a support substrate; a memory cell structure above the support substrate, the memory cell structure including memory cells in a main chip region; a peripheral circuit structure above the support substrate such that the peripheral circuit structure and the memory cell structure are stacked along a vertical direction, the peripheral circuit structure including peripheral circuit transistors in the main chip region; an intermediate substrate located between the memory cell structure and the peripheral circuit structure; a deep isolation insulating layer in a deep trench passing through the intermediate substrate; and a guard ring structure including a guard ring via in a guard ring region, wherein the guard ring structure passes through the deep isolation insulating layer and extends beyond an upper surface of the intermediate substrate and beyond a lower surface of the intermediate substrate.

### CROSS-REFERENCE TO RELATED APPLICATION

This application is based on and claims priority to Korean Patent Application No. 10-2024-0165605, filed on November 19, 2024, in the Korean Intellectual Property Office, the disclosure of which is incorporated by reference herein in its entirety.

### BACKGROUND

The present disclosure relates to a semiconductor memory device. More particularly, the present disclosure relates to a stack-type semiconductor memory device in which a memory cell structure and a peripheral circuit structure are stacked.

As semiconductor memory devices become more highly integrated, semiconductor elements in the semiconductor memory devices also become more highly integrated. Therefore, in order to highly integrate semiconductor elements and improve operation characteristics thereof, stack-type semiconductor memory devices in which memory cell structures and peripheral circuit structures are stacked have been studied.

### SUMMARY

One or more embodiments provide a stack-type semiconductor memory device having structural reliability.

According to an aspect of an embodiment, a semiconductor memory device has a main chip region and a guard ring region surrounding the main chip region. The semiconductor memory device includes: a support substrate; a memory cell structure above the support substrate, the memory cell structure including a plurality of memory cells in the main chip region; a peripheral circuit structure above the support substrate such that the peripheral circuit structure and the memory cell structure are stacked along a vertical direction, the peripheral circuit structure including a plurality of peripheral circuit transistors in the main chip region; an intermediate substrate located between the memory cell structure and the peripheral circuit structure; a deep isolation insulating layer in a deep trench passing through the intermediate substrate; and a guard ring structure including a guard ring via in the guard ring region, wherein the guard ring structure passes through the deep isolation insulating layer and extends beyond an upper surface of the intermediate substrate and beyond a lower surface of the intermediate substrate.

According to another aspect of an embodiment, a semiconductor memory device has a main chip region and a guard ring region. The guard ring region includes a chip guard ring region surrounding the main chip region and a scribe guard ring region surrounding the chip guard ring region. The semiconductor memory device includes: a base substrate; a memory cell structure above the base substrate and including a plurality of memory cells in the main chip region; a peripheral circuit structure above the memory cell structure, and including a peripheral circuit substrate located on a lower side of the peripheral circuit structure facing the memory cell structure and a plurality of peripheral circuit transistors on an upper surface of the peripheral circuit substrate in the main chip region; a deep isolation insulating layer in a deep trench passing through the peripheral circuit substrate; and a plurality of guard ring structures including a chip guard ring structure and a scribe guard ring structure. The chip guard ring structure passes through the deep isolation insulating layer in the chip guard ring region and extends beyond the upper surface of the peripheral circuit substrate and beyond a lower surface of the peripheral circuit substrate, and wherein the scribe guard ring structure passes through the deep isolation insulating layer in the scribe guard ring region beyond the upper surface of the peripheral circuit substrate beyond the lower surface of the peripheral circuit substrate. Each of the plurality of guard ring structures includes a guard ring via having a tapered shape extending with a horizontal width that decreases toward the base substrate, and wherein each of the plurality of guard ring structures passes through the deep isolation insulating layer.

According to another aspect of an embodiment, a semiconductor memory device has a main chip region and a guard ring region. The guard ring region includes a chip guard ring region surrounding the main chip region and a scribe guard ring region surrounding the chip guard ring region. The semiconductor memory device includes: a base substrate; a memory cell structure above the base substrate and including a plurality of memory cells in the main chip region; a peripheral circuit structure above the memory cell structure, the peripheral circuit structure including a peripheral circuit substrate located on a lower side of the peripheral circuit structure facing the memory cell structure, and a plurality of peripheral circuit transistors on an upper surface of the peripheral circuit substrate in the main chip region; a bonding insulating layer between the memory cell structure and a lower surface of the peripheral circuit substrate; a deep isolation insulating layer in a deep trench defined by the peripheral circuit substrate, the deep trench having a tapered shape extending with a horizontal width that decreases toward the base substrate; and a plurality of guard ring structures including a chip guard ring structure and a scribe guard ring structure, wherein the chip guard ring structure passes through the deep isolation insulating layer and the bonding insulating layer in the chip guard ring region and extends beyond the upper surface of the peripheral circuit substrate and beyond the lower surface of the peripheral circuit substrate, and the scribe guard ring structure passes through the deep isolation insulating layer and the bonding insulating layer in the scribe guard ring region and extends beyond the upper surface of the peripheral circuit substrate and beyond the lower surface of the peripheral circuit substrate. Each of the plurality of guard ring structures includes a guard ring via having a tapered shape extending with a horizontal width that decreases toward the base substrate. The memory cell structure includes: a capacitor structure with a capacitor lower electrode above the base substrate, a capacitor dielectric layer covering the capacitor lower electrode, and a capacitor upper electrode covering the capacitor lower electrode with the capacitor dielectric layer therebetween; a contact plug connected to the capacitor lower electrode above the capacitor structure; a channel pattern connected to the contact plug above the contact plug; a word line and a back gate electrode arranged on opposite sides of the channel pattern; a gate dielectric layer located between the channel pattern and the word line; a back gate dielectric layer located between the channel pattern and the back gate electrode; and a cell bit line connected to the channel pattern above the channel pattern, the word line, and the back gate electrode. The guard ring via in each of the plurality of guard ring structures has a linear and planar shape extending along a boundary between the chip guard ring region and the scribe guard ring region.

### BRIEF DESCRIPTION OF DRAWINGS

The above and other aspects will be more apparent from the following description of embodiments taken in conjunction with the accompanying drawings, in which:

FIG. 1 is a plan layout showing a semiconductor memory device according to embodiments;

Each of FIGS. 2A, 2B, 2C and 2D is a plan layout illustrating a portion of a guard ring region of a semiconductor memory device according to embodiments;

Each of FIGS. 3A, 3B, 3C and 3D is a cross-sectional view illustrating a semiconductor memory device according to embodiments;

FIGS. 4A and 4B are cross-sectional views illustrating a semiconductor memory device according to embodiments;

FIG. 5 is a cross-sectional view illustrating a semiconductor memory device according to embodiments;

FIG. 6 is a cross-sectional view illustrating a semiconductor memory device according to embodiments;

FIGS. 7A and 7B, FIGS. 8A and 8B, and FIGS. 9A and 9B are cross-sectional views illustrating a method of manufacturing a semiconductor memory device, according to embodiments; and

Each of FIGS. 10A and 10B is a plan layout illustrating a semiconductor memory device according to embodiments.

### DETAILED DESCRIPTION

Hereinafter, example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

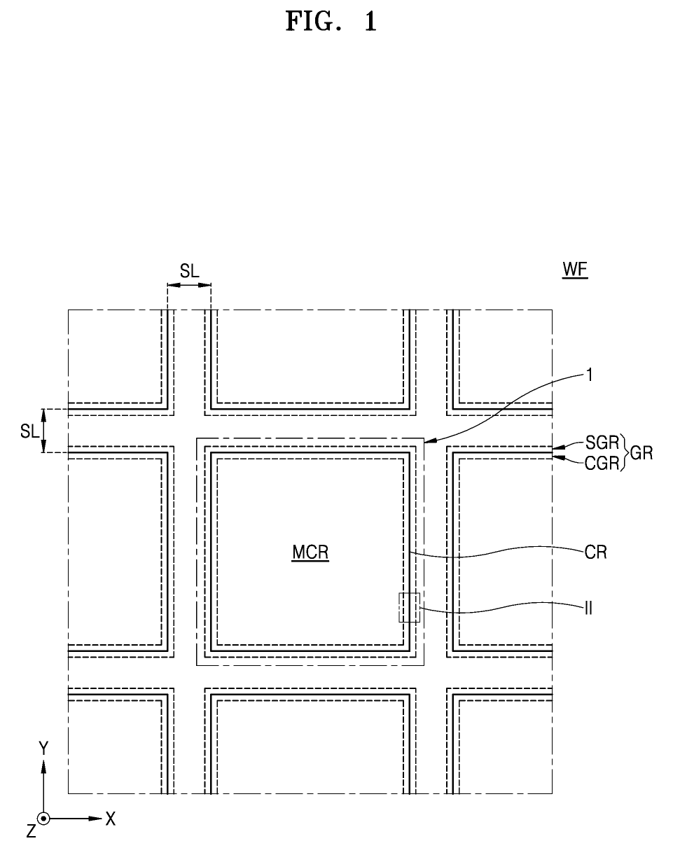

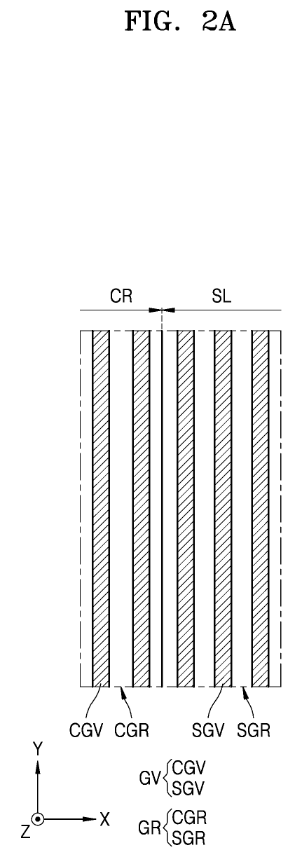

FIG. 1 is a plan layout illustrating a semiconductor wafer including a plurality of semiconductor memory devices according to embodiments.

Referring to FIG. 1, a plurality of semiconductor memory devices 1 may be formed on a semiconductor wafer WF. The semiconductor wafer WF has a plurality of chip regions CR defined by scribe lane regions SL. A scribe lane region SL may be located between the plurality of chip regions CR, and thus, the plurality of chip regions CR may be spaced apart from each other by the scribe lane region SL. Each of the plurality of semiconductor memory devices 1 may include one chip region CR. In some embodiments, each of the plurality of semiconductor memory devices 1 may include one chip region CR and a portion of a scribe lane region SL adjacent to the one chip region CR.

A guard ring region GR may have a planar shape extending along a boundary between each of the plurality of chip regions CR and the scribe lane region SL. The guard ring region GR may include a chip guard ring region CGR and a scribe guard ring region SGR surrounding the chip guard ring region CGR. The chip guard ring region CGR represents a portion of the chip region CR, which is adjacent to the scribe lane region SL, and the scribe guard ring region SGR represents a portion of the scribe lane region SL, which is adjacent to the chip region CR. The chip region CR may include a main chip region MCR and the chip guard ring region CGR. The chip guard ring region CGR may surround the main chip region MCR. In the main chip region MCR, components required to operate the semiconductor memory device 1 may be arranged. For example, a plurality of memory cells and a plurality of peripheral circuit transistors provided in the semiconductor memory device 1 may be arranged in the main chip region MCR, but not in the chip guard ring region CGR. The scribe guard ring region SGR may surround the chip region CR. The guard ring region GR may surround the main chip region MCR.

Each of the plurality of semiconductor memory devices 1 may include at least a portion of the scribe guard ring region SGR surrounding the chip region CR that is included in each of the plurality of semiconductor memory devices 1. In some embodiments, each of the plurality of semiconductor memory devices 1 may include the guard ring region GR, i.e., both the chip guard ring region CGR and the scribe guard ring region SGR, surrounding the main chip region MCR that is included in each of the plurality of semiconductor memory devices 1. In some embodiments, each of the plurality of semiconductor memory devices 1 may include all of the chip guard ring region CGR surrounding the main chip region MCR that is included in each of the plurality of semiconductor memory devices 1, but may include only a portion, adjacent to the chip region CR, of the scribe guard ring region SGR surrounding the chip region CR.

Each of FIGS. 2A to 2D is a plan layout illustrating a portion of a guard ring region of a semiconductor memory device according to embodiments. Specifically, each of FIGS. 2A to 2D is a plan layout showing an enlarged view of region II of FIG. 1. Each of FIGS. 3A to 3D is a cross-sectional view illustrating a semiconductor memory device according to embodiments.

Referring to FIG. 1 together with FIGS. 2A to 2D and FIGS. 3A to 3D, guard ring structures GRS (in FIGS. 3A to 3D) may be located in the guard ring region GR. The guard ring structures GRS may include chip guard ring structures CGS (in FIGS. 3A to 3D) and scribe guard ring structures SGS (in FIGS. 3A to 3D). Each of a chip guard ring structure CGS and a scribe guard ring structure SGS may extend in a vertical direction (a Z direction) as shown in FIGS. 3A to 3D. The chip guard ring structure CGS may be located in the chip guard ring region CGR and the scribe guard ring structure SGS may be located in the scribe guard ring region SGR. A guard ring structure GRS may include a guard ring via GV. The guard ring via GV may include a chip guard ring via CGV included in the chip guard ring structure CGS and a scribe guard ring via SGV included in the scribe guard ring structure SGS. The chip guard ring via CGV may include a portion, extending in the vertical direction (the Z direction), of the chip guard ring structure CGS. The scribe guard ring via SGV may include a portion, extending in the vertical direction (the Z direction), of the scribe guard ring structure SGS.

The planar arrangement of each of components of the chip guard ring structure CGS and the planar arrangement of each of components of the scribe guard ring structure SGS may be the same as the planar arrangement of chip guard ring vias CGV and scribe guard ring vias SGV shown in FIGS. 2A to 2D. For example, the planar arrangement of the components of the chip guard ring structure CGS may be the same as the planar arrangement of the chip guard ring vias CGV, but some of the components of the chip guard ring structure CGS may have a different horizontal width from that of the chip guard ring vias CGV. Also, the planar arrangement of the components of the scribe guard ring structure SGS is the same as the planar arrangement of the scribe guard ring vias SGV, but some of the components of the scribe guard ring structure SGS may have a different horizontal width from that of the scribe guard ring vias SGV.

Referring to FIGS. 1 and 2A together, each of the plurality of guard ring vias GV, including the chip guard ring via CGV and the scribe guard ring via SGV, may be located in the guard ring region GR and have a linear and planar shape extending along a boundary between the chip region CR and the scribe lane region SL. The guard ring region GR may include the chip guard ring region CGR and the scribe guard ring region SGR. At least one chip guard ring via CGV may be located in the chip guard ring region CGR, and at least one scribe guard ring via SGV may be located in the scribe guard ring region SGR.

The plurality of guard ring vias GV, including the chip guard ring vias CGV and the scribe guard ring vias SGV, may extend in the same direction as (i.e., parallel to) the boundary between the chip region CR and the scribe lane region SL, i.e., the boundary between the chip guard ring region CGR and the scribe guard ring region SGR, and may be spaced apart from each other in a direction perpendicular to the boundary between the chip guard ring region CGR and the scribe guard ring region SGR. For example, a portion of the chip guard ring via CGV and a portion of the scribe guard ring via SGV located in a region in which the boundary between the chip guard ring region CGR and the scribe guard ring region SGR extends in a first horizontal direction (an X direction) may be spaced apart from each other in a second horizontal direction (a Y direction) perpendicular to the first horizontal direction (the X direction) and may extend in the first horizontal direction (the X direction). For example, a portion of the chip guard ring via CGV and a portion of the scribe guard ring via SGV located in a region in which the boundary between the chip guard ring region CGR and the scribe guard ring region SGR that extend in the second horizontal direction (the Y direction) may be spaced apart from each other in the first horizontal direction (the X direction) and may extend in the second horizontal direction (the Y direction).

In some embodiments, the plurality of chip guard ring vias CGV may be arranged in the chip guard ring region CGR, the plurality of chip guard ring vias CGV may extend in the same direction as the boundary between the chip guard ring region CGR and the scribe guard ring region SGR, and may be spaced apart from each other in a direction perpendicular to the boundary between the chip guard ring region CGR and the scribe guard ring region SGR. In some embodiments, the plurality of scribe guard ring vias SGV may be arranged in the scribe guard ring region SGR, the plurality of scribe guard ring vias SGV may extend in the same direction as the boundary between the chip guard ring region CGR and the scribe guard ring region SGR, and may be spaced apart from each other in the direction perpendicular to the boundary between the chip guard ring region CGR and the scribe guard ring region SGR.

In some embodiments, the number of scribe guard ring vias SGV arranged in the scribe guard ring region SGR may be greater than the number of chip guard ring vias CGV arranged in the chip guard ring region CGR. FIG. 2A illustrates an example in which the number of scribe guard ring vias SGV arranged in the scribe guard ring region SGR is three, and the number of chip guard ring vias CGV arranged in the chip guard ring region CGR is two, but embodiments are not limited thereto. For example, the number of chip guard ring vias CGV arranged in the chip guard ring region CGR may be one or more, and the number of scribe guard ring vias SGV arranged in the scribe guard ring region SGR may be greater than the number of chip guard ring vias CGV arranged in the chip guard ring region CGR. For example, the number of scribe guard ring vias SGV arranged in the scribe guard ring region SGR may be two or more.

Referring to FIGS. 1 and 2B together, the chip guard ring via CGV may have a linear and planar shape extending along a boundary between the chip guard ring region CGR and the scribe guard ring region SGR. When two or more chip guard ring vias CGV are arranged in the chip guard ring region CGR, the two or more chip guard ring vias CGV may extend in parallel, and be spaced apart from each other in the direction perpendicular to the boundary between the chip guard ring region CGR and the scribe guard ring region SGR. A scribe guard ring via SGV may include at least two segments having a linear and planar shape, and extending in parallel along the boundary between the chip guard ring region CGR and the scribe guard ring region SGR. The scribe guard ring via SGV may also include a segment extending in a direction perpendicular to the boundary between the chip guard ring region CGR and the scribe guard ring region SGR and connecting the at least two segments having the linear and planar shape to each other.

Referring to FIGS. 1 and 2C together, a chip guard ring via CGV may include at least two segments having a linear and planar shape and extending in parallel along a boundary between the chip guard ring region CGR and the scribe guard ring region SGR. The chip guard ring via CGV may also include and a segment extending in a direction perpendicular to the boundary between the chip guard ring region CGR and the scribe guard ring region SGR and connecting the at least two segments having the linear and planar shape to each other. The scribe guard ring via SGV may have a linear and planar shape extending along the boundary between the chip guard ring region CGR and the scribe guard ring region SGR. When two or more scribe guard ring vias SGV are arranged in the scribe guard ring region SGR, the two or more scribe guard ring vias SGV may be spaced apart from each other in the direction perpendicular to the boundary between the chip guard ring region CGR and the scribe guard ring region SGR, and may extend in parallel along the boundary between the chip guard ring region CGR and the scribe guard ring region SGR.

Referring to FIGS. 1 and 2D, a chip guard ring via CGV may include at least two segments having a linear and planar shape and extending in parallel along a boundary between the chip guard ring region CGR and the scribe guard ring region SGR, and a segment extending in a direction perpendicular to the boundary between the chip guard ring region CGR and the scribe guard ring region SGR and connecting the at least two segments having the linear and planar shape to each other. A scribe guard ring via SGV may include at least two segments having a linear and planar shape and extending in parallel along the boundary between the chip guard ring region CGR and the scribe guard ring region SGR, and a segment extending in a direction perpendicular to the boundary between the chip guard ring region CGR and the scribe guard ring region SGR and connecting the at least two segments having the linear and planar shape to each other.

Referring to FIG. 3A, a semiconductor memory device 1 may include a chip region CR defined by a scribe lane region SL. The chip region CR and the scribe lane region SL may include a chip guard ring region CGR and a scribe guard ring region SGR, respectively, which are adjacent to each other. The chip guard ring region CGR and the scribe guard ring region SGR may be referred to together as a guard ring region GR. The chip region CR may include a main chip region MCR and the chip guard ring region CGR. The scribe lane region SL shown in FIG. 3A may represent a portion of the scribe lane region SL shown in FIG. 1. For example, the scribe lane region SL shown in FIG. 3A may represent a portion of the scribe lane region SL shown in FIG. 1 that remains after the scribe lane region SL is partially removed during a process of separating each of the plurality of semiconductor memory devices 1 from the semiconductor wafer WF shown in FIG. 1, and may represent a portion of the scribe lane region SL, which is adjacent to one chip region CR shown in FIG. 1.

The semiconductor memory device 1 includes a base substrate BSUB, a memory cell structure MCS above the base substrate BSUB, and a peripheral circuit structure PCRT above the memory cell structure MCS. The base substrate BSUB may be located across the chip region CR and the scribe lane region SL. The memory cell structure MCS and the peripheral circuit structure PCRT may be disposed above the base substrate BSUB in the main chip region MCR. In some embodiments, a portion of the guard ring region GR, which is located at the same vertical level as the memory cell structure MCS, may represent a portion of the memory cell structure MCS, and a portion of the guard ring region GR, which is located at the same vertical level as the peripheral circuit structure PCRT, may represent a portion of the peripheral circuit structure PCRT. In some embodiments, the semiconductor memory device 1 may have a periphery on cell (PoC) structure in which the memory cell structure MCS and the peripheral circuit structure PCRT overlap each other in a vertical direction (a Z direction).

The memory cell structure MCS may include a plurality of memory cells. The plurality of memory cells may include, for example, dynamic random-access memory (DRAM), static random-access memory (SRAM), flash memory, electrically erasable and programmable read-only memory (EPROM), phase-change random-access memory (PRAM), magnetic random-access memory (MRAM), or resistive random-access memory (RRAM). In some embodiments, the DRAM may include recess channel array transistor (RCAT) DRAM, buried channel array transistor (BCAT) DRAM, vertical channel transistor (VCT) DRAM, or a 3D DRAM such as vertically stacked DRAM (VSDRAM). In some embodiments, the flash memory may include a vertical NAND (VNAND). The peripheral circuit structure PCRT may include a plurality of peripheral circuit transistors for driving the memory cell structure MCS.

The semiconductor memory device 1 may further include a plurality of guard ring structures GRS above the base substrate BSUB. Each of the plurality of guard ring structures GRS may include a metal-containing material. For example, each of the plurality of guard ring structures GRS may include a metal material, metal nitride, or metal silicide. The plurality of guard ring structures GRS may include at least one chip guard ring structure CGS and at least one scribe guard ring structure SGS. The chip guard ring structure CGS may be disposed above the base substrate BSUB in the chip guard ring region CGR, and the scribe guard ring structure SGS may be disposed above the base substrate BSUB in the scribe guard ring region SGR.

The peripheral circuit structure PCRT may include a peripheral circuit substrate PSUB. The peripheral circuit substrate PSUB may be located in a portion of the peripheral circuit structure PCRT, which faces the memory cell structure MCS, i.e., on a lower side of the peripheral circuit structure PCRT. That is, the peripheral circuit substrate PSUB may be stacked above the memory cell structure MCS, and the peripheral circuit structure PCRT may be formed across at least a portion of the peripheral circuit substrate PSUB on the upper side of the peripheral circuit substrate PSUB. A bonding insulating layer BDI may be formed on the lower surface of the peripheral circuit substrate PSUB. The peripheral circuit structure PCRT may be bonded to the memory cell structure MCS via the bonding insulating layer BDI. For example, the bonding insulating layer BDI and an insulating layer located above the memory cell structure MCS may be covalently bonded to each other, and thus, the memory cell structure MCS may be bonded to the peripheral circuit structure PCRT. For example, the memory cell structure MCS may be formed separately, turned over, and then attached to the base substrate BSUB. After at least a portion of the peripheral circuit structure PCRT including the peripheral circuit substrate PSUB may be formed separately, and the peripheral circuit structure PCRT may be attached to the memory cell structure MCS such that the peripheral circuit substrate PSUB faces the memory cell structure MCS attached to the base substrate BSUB.

The memory cell structure MCS may be electrically connected to the peripheral circuit structure PCRT through a cell peripheral circuit connection via CPIV. The cell peripheral circuit connection via CPIV may pass through the peripheral circuit substrate PSUB and extend toward each of the upper side and the lower side of the peripheral circuit substrate PSUB. For example, the uppermost end of the cell peripheral circuit connection via CPIV may be at a vertical level higher than the upper surface of the peripheral circuit substrate PSUB, and the lowermost end of the cell peripheral circuit connection via CPIV may be at a vertical level lower than the lower surface of the peripheral circuit substrate PSUB.

Each of the plurality of guard ring structures GRS may include a guard upper pattern GSUP, a peripheral circuit connection structure PITS, a via upper line pattern GVUP, a guard ring via GV that is located in the guard ring region GR and passes through the peripheral circuit substrate PSUB, a via lower line pattern GVLP, a cell connection structure CITS and a guard lower pattern GSLP. The at least one chip guard ring structure CGS and the at least one scribe guard ring structure SGS, which are included in each of the plurality of guard ring structures GRS, may have substantially the same structure. For example, each of the at least one chip guard ring structure CGS and the at least one scribe guard ring structure SGS, which are included in each of the plurality of guard ring structures GRS, may include the guard ring via GV. Hereinafter, the description of the guard ring structure GRS may be the same as the description of each of the at least one chip guard ring structure CGS and the at least one scribe guard ring structure SGS.

The guard ring via GV may pass through the peripheral circuit substrate PSUB and extend toward each of the upper side and the lower side of the peripheral circuit substrate PSUB. For example, the uppermost end of the guard ring via GV may be at a vertical level lower than the uppermost end of the guard ring structure GRS but higher than the upper surface of the peripheral circuit substrate PSUB, and the lowermost end of the guard ring via GV may be at a vertical level higher than the lowermost end of the guard ring structure GRS but lower than the lower surface of the peripheral circuit substrate PSUB. In some embodiments, the cell peripheral circuit connection via CPIV may be at the same vertical level as the guard ring via GV. For example, the uppermost end of the cell peripheral circuit connection via CPIV may be at the same vertical level as the uppermost end of the guard ring via GV, and the lowermost end of the cell peripheral circuit connection via CPIV may be at the same vertical level as the lowermost end of the guard ring via GV. Each of the cell peripheral circuit connection via CPIV and the guard ring via GV may be provided as a single body from the uppermost end to the lowermost end thereof.

The peripheral circuit connection structure PITS may be disposed above the cell peripheral circuit connection via CPIV and the guard ring via GV, and the cell connection structure CITS may be disposed below the cell peripheral circuit connection via CPIV and the guard ring via GV. Each of the peripheral circuit connection structure PITS and the cell connection structure CITS may include at least one line pattern and at least one via connected to the at least one line pattern.

The via upper line pattern GVUP may be located between the peripheral circuit connection structure PITS and each of the cell peripheral circuit connection via CPIV and the guard ring via GV, and the via lower line pattern GVLP may be located between the cell connection structure CITS and each of the cell peripheral circuit connection via CPIV and the guard ring via GV. For example, the via upper line pattern GVUP may be connected to the upper end of each of the cell peripheral circuit connection via CPIV and the guard ring via GV, and the via lower line pattern GVLP may be connected to the lower end of each of the cell peripheral circuit connection via CPIV and the guard ring via GV.

The guard upper pattern GSUP may be connected to the upper end of the guard ring structure GRS, and the guard lower pattern GSLP may be connected to the lower end of the guard ring structure GRS. The upper surface of the guard upper pattern GSUP may represent the uppermost end of the guard ring structure GRS, and the lower surface of the guard lower pattern GSLP may represent the lowermost end of the guard ring structure GRS.

The peripheral circuit substrate PSUB may have, or define, a deep trench DTR that passes through the peripheral circuit substrate PSUB. A deep isolation insulating layer DTI may fill the deep trench DTR. Each of the cell peripheral circuit connection via CPIV and the guard ring via GV may pass through the deep isolation insulating layer DTI that fills the deep trench DTR and may extend toward each of the upper side and the lower side of the peripheral circuit substrate PSUB. Each of the cell peripheral circuit connection via CPIV and the guard ring via GV may be spaced apart from the peripheral circuit substrate PSUB with a portion of the deep isolation insulating layer DTI therebetween. For example, the deep trench DTR may have a tapered shape that has a wider portion facing the peripheral circuit structure PCRT, and a narrower portion facing the memory cell structure MCS and the base substrate BSUB.

Each of the cell peripheral circuit connection via CPIV and the guard ring via GV may have a tapered shape that extends with a horizontal width decreasing from the upper side to the lower side thereof. For example, each of the cell peripheral circuit connection via CPIV and the guard ring via GV may have a tapered shape that extends with a horizontal width decreasing toward the base substrate BSUB. Each of the deep isolation insulating layer DTI and the deep trench DTR may have a tapered shape that extends with a horizontal width decreasing from the upper side to the lower side thereof. For example, each of the deep isolation insulating layer DTI and the deep trench DTR may have a tapered shape that extends with a horizontal width decreasing toward the base substrate BSUB. For example, each of the cell peripheral circuit connection via CPIV and the guard ring via GV may have a tapered shape that is wider in the peripheral circuit structure PCRT than in the memory cell structure MCS.

Referring to FIG. 3B, a semiconductor memory device 1a includes a base substrate BSUB, a peripheral circuit structure PCRT above the base substrate BSUB, and a memory cell structure MCS above the peripheral circuit structure PCRT. The semiconductor memory device 1a may further include a plurality of guard ring structures GRS above the base substrate BSUB. In some embodiments, the semiconductor memory device 1a may have a cell on periphery (CoP) structure in which the memory cell structure MCS and the peripheral circuit structure PCRT overlap each other in a vertical direction (a Z direction).

The peripheral circuit structure PCRT may include a peripheral circuit substrate PSUB. The peripheral circuit substrate PSUB may be located in a portion of the peripheral circuit structure PCRT, which faces the memory cell structure MCS. That is, the memory cell structure MCS may be stacked above the peripheral circuit substrate PSUB, and the peripheral circuit structure PCRT may be formed across at least a portion of the peripheral circuit substrate PSUB on the lower side of the peripheral circuit substrate PSUB. A bonding insulating layer BDI may be formed on the upper surface of the peripheral circuit substrate PSUB. The memory cell structure MCS may be bonded to the peripheral circuit structure PCRT via the bonding insulating layer BDI. For example, the peripheral circuit structure PCRT including the peripheral circuit substrate PSUB may be formed separately, turned over, and then attached to the base substrate BSUB. The memory cell structure MCS may be formed separately, turned over, and then attached to the peripheral circuit substrate PSUB.

The memory cell structure MCS may be electrically connected to the peripheral circuit structure PCRT through a cell peripheral circuit connection via CPIV. The cell peripheral circuit connection via CPIV may pass through the peripheral circuit substrate PSUB and extend toward each of the upper side and the lower side of the peripheral circuit substrate PSUB. Each of the plurality of guard ring structures GRS may include a guard ring via GV that is located in the guard ring region GR and passes through the peripheral circuit substrate PSUB. The guard ring via GV may pass through the peripheral circuit substrate PSUB and extend toward each of the upper side and the lower side of the peripheral circuit substrate PSUB.

A cell connection structure CITS may be disposed above the cell peripheral circuit connection via CPIV and the guard ring via GV, and a peripheral circuit connection structure PITS may be disposed below the cell peripheral circuit connection via CPIV and the guard ring via GV.

A via upper line pattern GVUP may be located between the cell connection structure CITS and each of the cell peripheral circuit connection via CPIV and the guard ring via GV, and a via lower line pattern GVLP may be located between the peripheral circuit connection structure PITS and each of the cell peripheral circuit connection via CPIV and the guard ring via GV.

Each of the cell peripheral circuit connection via CPIV and the guard ring via GV may pass through a deep isolation insulating layer DTI that fills a deep trench DTR and may extend toward each of the upper side and the lower side of the peripheral circuit substrate PSUB. Each of the cell peripheral circuit connection via CPIV and the guard ring via GV may have a tapered shape that extends with a horizontal width decreasing from the upper side to the lower side thereof. Each of the deep isolation insulating layer DTI and the deep trench DTR may have a tapered shape that extends with a horizontal width increasing from the upper side to the lower side thereof. For example, each of the deep isolation insulating layer DTI and the deep trench DTR may have a tapered shape that extends with a horizontal width increasing toward the base substrate BSUB. For example, the deep trench DTR may have a wider portion facing the peripheral circuit structure PCRT and the base substrate BSUB, and a narrower portion facing the memory cell structure MCS.

Referring to FIG. 3C, a semiconductor memory device 1b includes a base substrate BSUB, a memory cell structure MCS above the base substrate BSUB, and a peripheral circuit structure PCRT above the memory cell structure MCS. The semiconductor memory device 1b may further include a plurality of guard ring structures GRS above the base substrate BSUB. In some embodiments, the semiconductor memory device 1b may have a PoC structure in which the memory cell structure MCS and the peripheral circuit structure PCRT overlap each other in a vertical direction (a Z direction).

The peripheral circuit structure PCRT may include a peripheral circuit substrate PSUB. The peripheral circuit substrate PSUB may be located in a portion of the peripheral circuit structure PCRT, which is opposite the memory cell structure MCS. That is, the peripheral circuit structure PCRT may be stacked above the memory cell structure MCS such that the peripheral circuit substrate PSUB is positioned on the opposite side from the memory cell structure MCS, and the peripheral circuit structure PCRT may be formed across at least a portion of the peripheral circuit substrate PSUB on the lower side of the peripheral circuit substrate PSUB. A bonding insulating layer BDIa and a plurality of bonding pads BPD may be arranged between the memory cell structure MCS and the peripheral circuit structure PCRT. The bonding insulating layer BDIa may be formed by bonding a cell bonding insulating layer BDIC, which is located on the upper side of the memory cell structure MCS, to a peripheral circuit bonding insulating layer BDIP, which is located on the lower side of the peripheral circuit structure PCRT. Each of the plurality of bonding pads BPD may be formed by bonding a cell bonding pad BPDC, which is surrounded by the cell bonding insulating layer BDIC, to a peripheral circuit bonding pad BPDP, which is surrounded by the peripheral circuit bonding insulating layer BDIP.

The peripheral circuit structure PCRT may be bonded to the memory cell structure MCS via the bonding insulating layer BDIa and the plurality of bonding pads BPD. For example, the cell bonding insulating layer BDIC and the peripheral circuit bonding insulating layer BDIP may be covalently bonded together to form the bonding insulating layer BDIa. Also, the cell bonding pad BPDC and the peripheral circuit bonding pad BPDP may be arranged facing each other, thermally expanded and brought into contact with each other, and diffusion-bonded to each other via diffusion of metal atoms therein to form a single body, thereby forming each of the plurality of bonding pads BPD. The memory cell structure MCS may be bonded to the peripheral circuit structure PCRT by a hybrid bonding method. For example, the memory cell structure MCS may be formed separately, turned over, and then attached to the base substrate BSUB. After at least a portion of the peripheral circuit structure PCRT including the peripheral circuit substrate PSUB is formed separately and turned over, the peripheral circuit structure PCRT may be attached to the memory cell structure MCS by the hybrid bonding method such that the peripheral circuit substrate PSUB faces an upper side opposite to the memory cell structure MCS attached to the base substrate BSUB.

The memory cell structure MCS may be electrically connected to the peripheral circuit structure PCRT through a cell peripheral circuit connection via CPIVa. The cell peripheral circuit connection via CPIVa may include a cell connection via CPIVC and a peripheral circuit connection via CPIVP. Each of the plurality of guard ring structures GRS may include a guard ring via GVa that is located in the guard ring region GR. The guard ring via GVa may include a cell guard ring via GVC and a peripheral circuit guard ring via GVP. The bonding pads BPD may be respectively provided between the cell connection via CPIVC and the peripheral circuit connection via CPIVP, which are included in the cell peripheral circuit connection via CPIVa, and between the cell guard ring via GVC and the peripheral circuit guard ring via GVP, which are included in the guard ring via GVa. For example, the cell connection via CPIVC and the peripheral circuit connection via CPIVP, which are included in the cell peripheral circuit connection via CPIVa, may be electrically connected to each other via the bonding pad BPD, and the cell guard ring via GVC and the peripheral circuit guard ring via GVP, which are included in the guard ring via GVa, may be electrically connected to each other via the bonding pad BPD. Each of the cell connection via CPIVC and the cell guard ring via GVC may extend from the bonding pad BPD into the memory cell structure MCS, and each of the peripheral circuit connection via CPIVP and the peripheral circuit guard ring via GVP may extend from the bonding pad BPD into the peripheral circuit structure PCRT.

A peripheral circuit connection structure PITS may be disposed above the peripheral circuit connection via CPIVP and a peripheral circuit guard ring via GVP, and a cell connection structure CITS may be disposed below the cell connection via CPIVC and the cell guard ring via GVC. A via upper line pattern GVUP may be located between the peripheral circuit connection structure PITS and each of peripheral circuit connection via CPIVP and the peripheral circuit guard ring via GVP, and a via lower line pattern GVLP may be located between the cell connection structure CITS and each of the cell connection via CPIVC and the cell guard ring via GVC. A guard upper pattern GSUP may be connected to the upper end of the guard ring structure GRS, and a guard lower pattern GSLP may be connected to the lower end of the guard ring structure GRS.

The peripheral circuit substrate PSUB may have a deep trench DTR that passes through the peripheral circuit substrate PSUB, and a deep isolation insulating layer DTI may fill the deep trench DTR. In some embodiments, an isolation layer extension structure DITS may be disposed on the guard upper pattern GSUP, and may be connected to the upper surface of the guard upper pattern GSUP and extend into the deep isolation insulating layer DTI that fills the deep trench DTR. The guard ring structure GRS may include the isolation layer extension structure DITS. The guard ring structure GRS may overlap, in the vertical direction (the Z direction), the deep isolation insulating layer DTI that fills the deep trench DTR. The guard ring structure GRS may not overlap the peripheral circuit substrate PSUB in the vertical direction (the Z direction).

Each of the cell connection via CPIVC and the cell guard ring via GVC may have a tapered shape that extends with a horizontal width decreasing from the upper side to the lower side thereof. For example, each of the cell connection via CPIVC and the cell guard ring via GVC may have a tapered shape that extends with a horizontal width decreasing toward the base substrate BSUB. Each of the peripheral circuit connection via CPIVP and the peripheral circuit guard ring via GVP may have a tapered shape that extends with a horizontal width increasing from the upper side to the lower side thereof. For example, each of the peripheral circuit connection via CPIVP and the peripheral circuit guard ring via GVP may have a tapered shape that extends with a horizontal width increasing toward the base substrate BSUB. Each of the deep isolation insulating layer DTI and the deep trench DTR may have a tapered shape that extends with a horizontal width increasing from the upper side to the lower side thereof. For example, each of the deep isolation insulating layer DTI and the deep trench DTR may have a tapered shape that extends with a horizontal width increasing toward the base substrate BSUB.

Referring to FIG. 3D, a semiconductor memory device 1c includes a peripheral circuit structure PCRT, including a peripheral circuit substrate PSUB, and a memory cell structure MCS above the peripheral circuit structure PCRT. The semiconductor memory device 1c may further include a plurality of guard ring structures GRS above the peripheral circuit substrate PSUB. The peripheral circuit substrate PSUB may be located in a portion of the peripheral circuit structure PCRT, which is opposite the memory cell structure MCS. For example, the peripheral circuit substrate PSUB may be located on the lower side of the peripheral circuit structure PCRT. In some embodiments, the semiconductor memory device 1c may have a CoP structure in which the memory cell structure MCS and the peripheral circuit structure PCRT overlap each other in a vertical direction (a Z direction).

A bonding insulating layer BDIa and a plurality of bonding pads BPD may be arranged between the memory cell structure MCS and the peripheral circuit structure PCRT. The bonding insulating layer BDIa may be formed by bonding a cell bonding insulating layer BDIC, which is located on the lower side of the memory cell structure MCS, to a peripheral circuit bonding insulating layer BDIP, which is located on the upper side of the peripheral circuit structure PCRT. Each of the plurality of bonding pads BPD may be formed by bonding a cell bonding pad BPDC, which is surrounded by the cell bonding insulating layer BDIC, to a peripheral circuit bonding pad BPDP, which is surrounded by the peripheral circuit bonding insulating layer BDIP. The memory cell structure MCS may be bonded to the peripheral circuit structure PCRT via the bonding insulating layer BDIa and the plurality of bonding pads BPD. The memory cell structure MCS may be bonded to the peripheral circuit structure PCRT by a hybrid bonding method. For example, after the peripheral circuit structure PCRT including the peripheral circuit substrate PSUB is formed, the memory cell structure MCS may be turned over and attached to the peripheral circuit structure PCRT.

A cell connection structure CITS may be disposed above a cell connection via CPIVC and a cell guard ring via GVC, and a peripheral circuit connection structure PITS may be disposed below a peripheral circuit connection via CPIVP and a peripheral circuit guard ring via GVP. A via upper line pattern GVUP may be located between the cell connection structure CITS and each of the cell connection via CPIVC and the cell guard ring via GVC, and a via lower line pattern GVLP may be located between the peripheral circuit connection structure PITS and each of the peripheral circuit connection via CPIVP and the peripheral circuit guard ring via GVP. A guard upper pattern GSUP may be connected to the upper end of the guard ring structure GRS, and a guard lower pattern GSLP may be connected to the lower end of the guard ring structure GRS.

Each of the cell connection via CPIVC and the cell guard ring via GVC may have a tapered shape that extends with a horizontal width increasing from the upper side to the lower side thereof. For example, each of the cell connection via CPIVC and the cell guard ring via GVC may have a tapered shape that extends with a horizontal width increasing toward the peripheral circuit substrate PSUB. Each of the peripheral circuit connection via CPIVP and the peripheral circuit guard ring via GVP may have a tapered shape that extends with a horizontal width decreasing from the upper side to the lower side thereof. For example, each of the peripheral circuit connection via CPIVP and the peripheral circuit guard ring via GVP may have a tapered shape that extends with a horizontal width decreasing toward the peripheral circuit substrate PSUB.

Referring to FIGS. 3A to 3D, the semiconductor memory devices 1, 1a, 1b, and 1c include the plurality of guard ring structures GRS including the guard ring vias GV and GVa that extend from a region between the memory cell structure MCS and the peripheral circuit structure PCRT toward each of the memory cell structure MCS and the peripheral circuit structure PCRT. The plurality of guard ring structures GRS may also include the guard upper pattern GSUP, the peripheral circuit connection structure PITS, the via upper line pattern GVUP, the via lower line pattern GVLP, the cell connection structure CITS, the guard lower pattern GSLP and the isolation layer extension structure DITS. Thus, the plurality of guard ring structures GRS may prevent cracks from propagating inside the plurality of semiconductor memory devices 1, 1a, 1b, and 1c during the process of separating each of the plurality of semiconductor memory devices 1, 1a, 1b, and 1c from the semiconductor wafer WF shown in FIG. 1.

The base substrates BSUB shown in FIGS. 3A to 3C and the peripheral circuit substrate PSUB shown in FIG. 3D may be referred to as a support substrate, the peripheral circuit substrates PSUB shown in FIGS. 3A and 3B may be referred to as an intermediate substrate, and the peripheral circuit substrate PSUB shown in FIG. 3C may be referred to as a cover substrate. Each of the base substrate BSUB and the peripheral circuit substrate PSUB may include, for example, semiconductor materials, such as a group IV semiconductor material, a group III-V semiconductor material or a group II-VI semiconductor material, and a group II-VI oxide semiconductor material.

In the semiconductor memory devices 1 and 1a respectively shown in FIGS. 3A and 3B, the guard ring via GV, which is integrally and continuously formed, extends from the memory cell structure MCS to the peripheral circuit structure PCRT via the deep isolation insulating layer DTI that fills the deep trench DTR of the intermediate substrate. Therefore, during the process of separating each of the plurality of semiconductor memory devices 1 and 1a from the semiconductor wafer WF shown in FIG. 1, cracks may be prevented from propagating into the intermediate substrate that is included in each of the plurality of semiconductor memory devices 1 and 1a. The semiconductor memory devices 1b and 1c respectively shown in FIGS. 3C and 3D include the guard ring via GVa which extends from the memory cell structure MCS to the peripheral circuit structure PCRT and in which the cell guard ring via GVC and the peripheral circuit guard ring via GVP are bonded to each other by the bonding pad BPD, but does not include the intermediate substrate. Also, the semiconductor memory devices 1b and 1c respectively shown in FIGS. 3C and 3D may have the deep isolation insulating layer DTI that fills the deep trench DTR and may thus prevent cracks from propagating inside the plurality of semiconductor memory devices 1b and 1c during the process of separating each of the plurality of semiconductor memory devices 1b and 1c from the semiconductor wafer WF shown in FIG. 1, thereby achieving structural reliability.

While FIGS. 3A to 3D show that the semiconductor memory devices 1, 1a, 1b, and 1c include the plurality of guard ring structures GRS, it will be apparent to those skilled in the art that the semiconductor memory devices 1, 1a, 1b, and 1c may include other structures, such as a chipping dam structure located in the scribe lane region SL, in addition to the guard ring structure GRS.

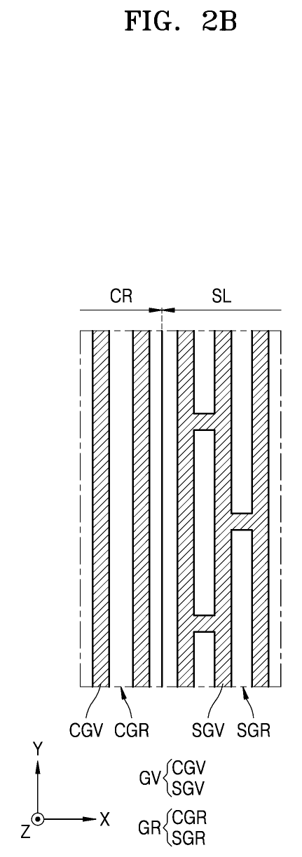

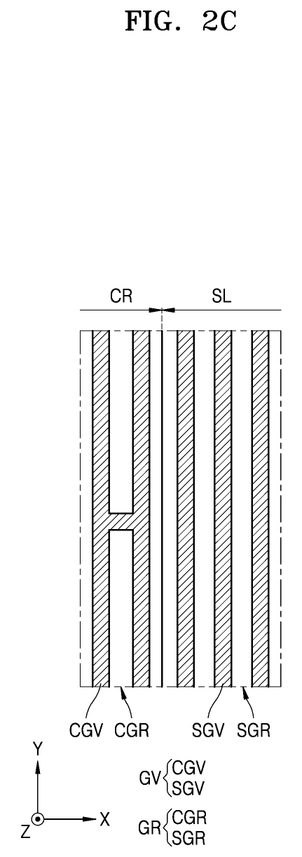

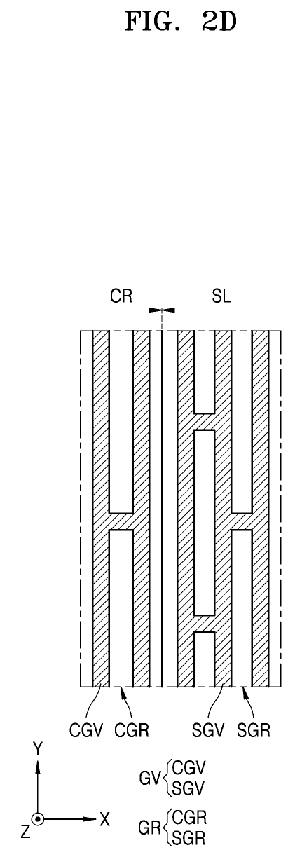

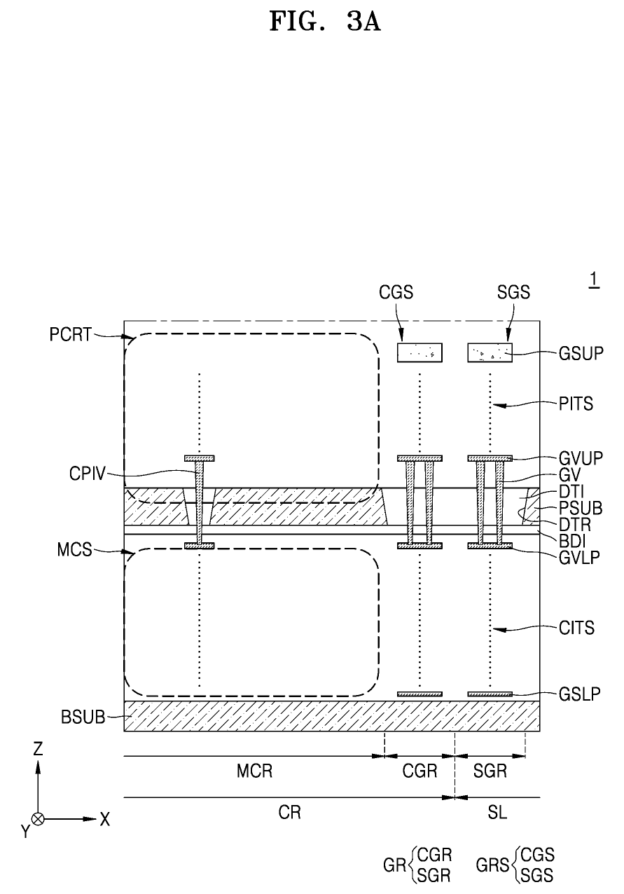

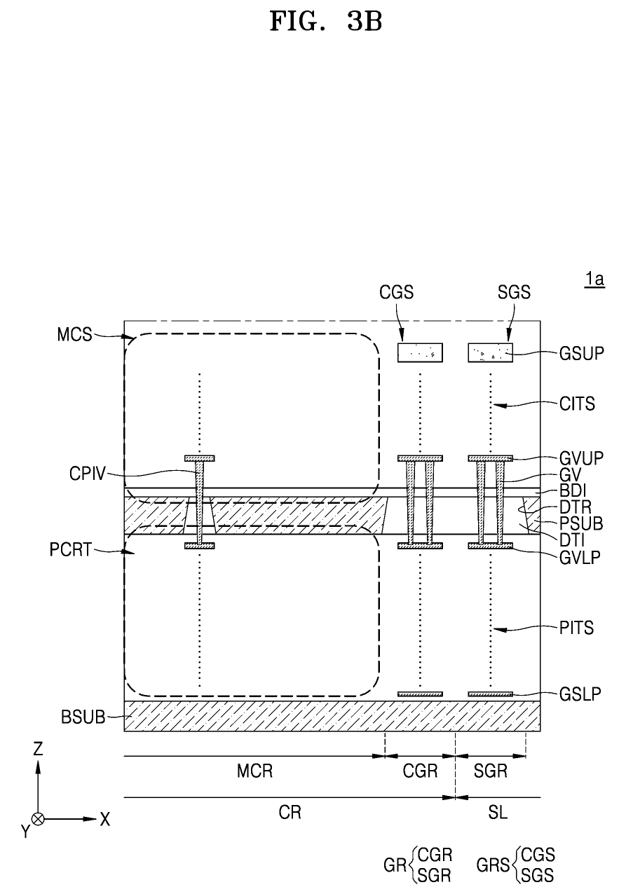

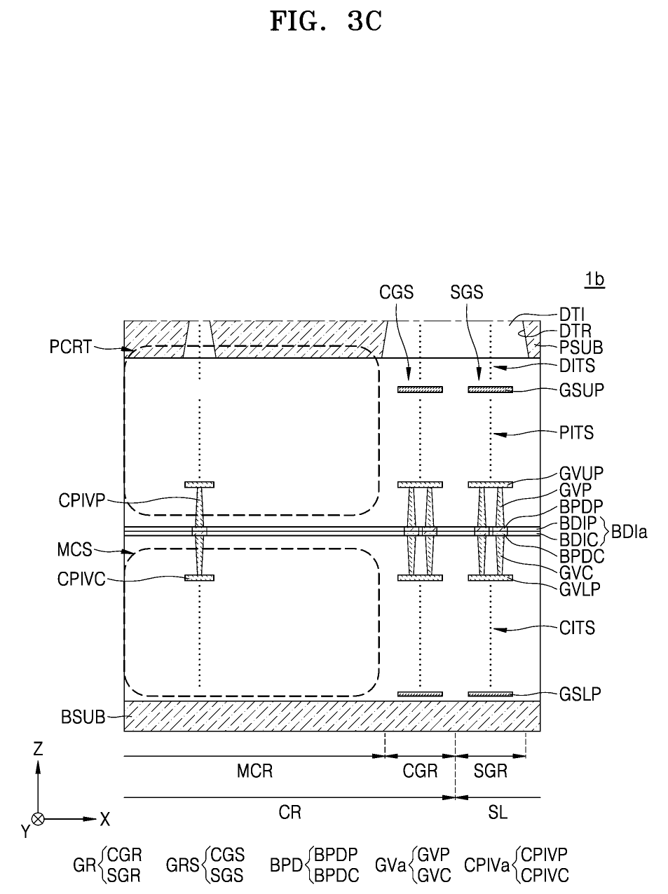

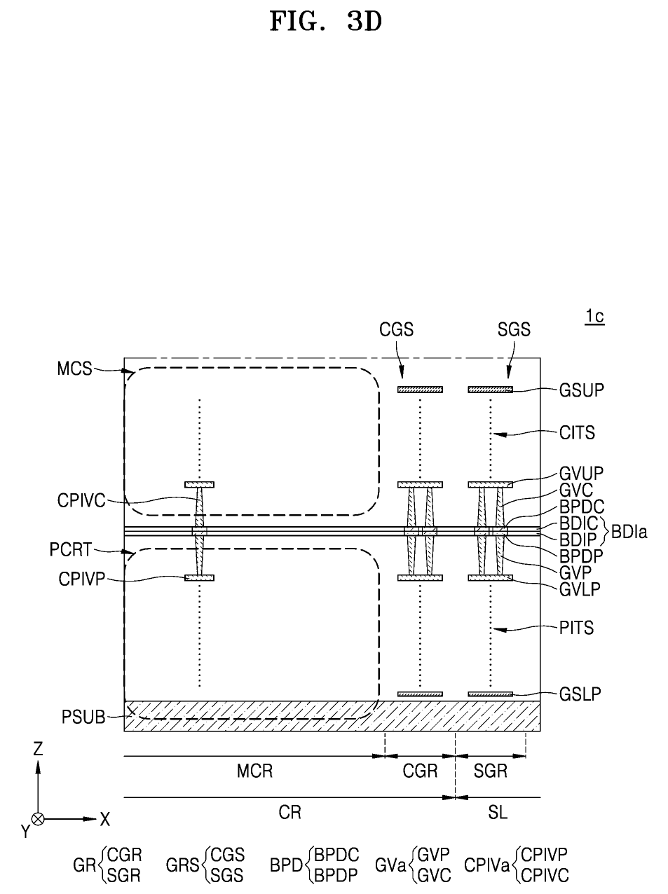

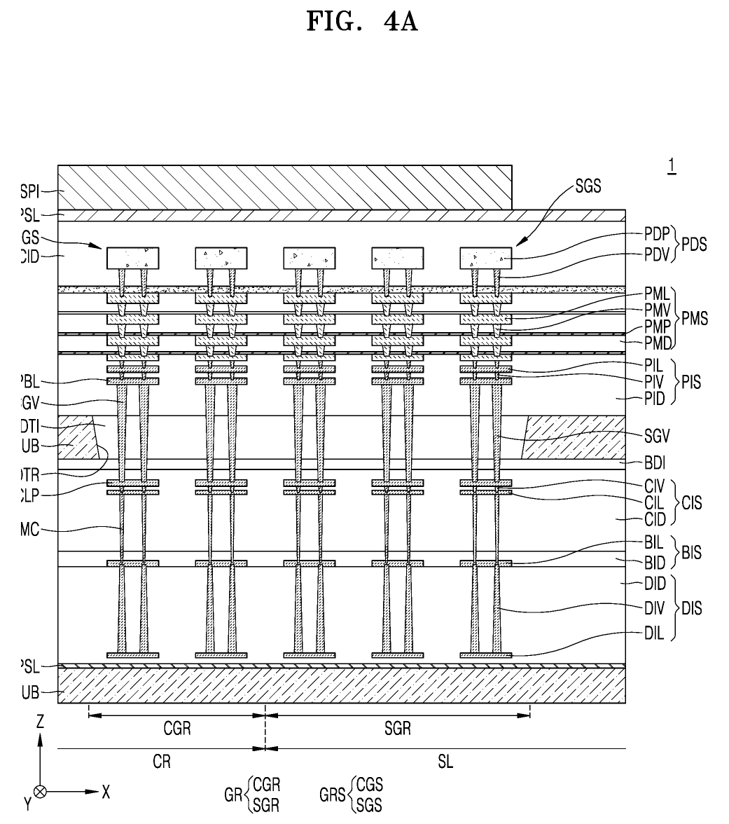

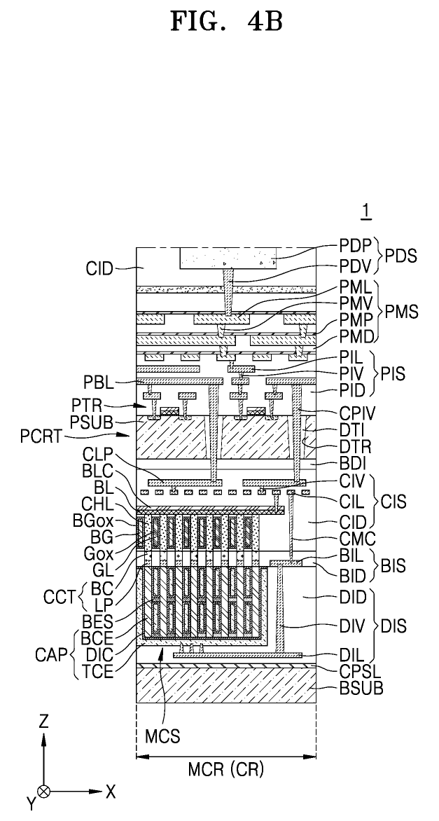

FIGS. 4A and 4B are cross-sectional views illustrating a semiconductor memory device 1 according to embodiments.

Referring to FIGS. 4A and 4B together, the semiconductor memory device 1 may include a chip region CR defined by a scribe lane region SL. The chip region CR and the scribe lane region SL may include a chip guard ring region CGR and a scribe guard ring region SGR, respectively, which are adjacent to each other. The chip region CR may include a main chip region MCR and the chip guard ring region CGR.

The semiconductor memory device 1 includes a base substrate BSUB, a memory cell structure MCS above the base substrate BSUB, and a peripheral circuit structure PCRT above the memory cell structure MCS. The memory cell structure MCS may include a plurality of memory cells. FIG. 4A illustrates an example in which the memory cell structure MCS includes VCT DRAM. The peripheral circuit structure PCRT may include a peripheral circuit substrate PSUB and a plurality of peripheral circuit transistors PTR. The plurality of peripheral circuit transistors PTR may be disposed on the upper surface of the peripheral circuit substrate PSUB. The plurality of peripheral circuit transistors PTR may be configured to deliver signals and/or power to a plurality of memory cells in the memory cell structure MCS. For example, the plurality of peripheral circuit transistors PTR may constitute various circuits, such as a command decoder, control logic, an address buffer, a row decoder, a column decoder, a sense amplifier, and a data input/output circuit. FIG. 4B illustrates that a peripheral circuit transistor PTR includes a planar transistor, but embodiments are not limited thereto. For example, the peripheral circuit transistor PTR may include a fin-type field effect transistor (FinFET) or a vertical gate transistor. A bonding insulating layer BDI may be formed on the lower surface of the peripheral circuit substrate PSUB. The peripheral circuit structure PCRT may be bonded to the memory cell structure MCS via the bonding insulating layer BDI. The semiconductor memory device 1 may further include a plurality of guard ring structures GRS above the base substrate BSUB. The plurality of guard ring structures GRS may include at least one chip guard ring structure CGS and at least one scribe guard ring structure SGS.

The memory cell structure MCS may be electrically connected to the peripheral circuit structure PCRT through a cell peripheral circuit connection via CPIV. Each of the plurality of guard ring structures GRS may include a guard ring via GV that is located in the guard ring region GR and passes through the peripheral circuit substrate PSUB. In some embodiments, the cell peripheral circuit connection via CPIV may be at the same vertical level as the guard ring via GV.

A peripheral circuit bit line pattern PBL may be connected to an upper side of each of the cell peripheral circuit connection via CPIV and the guard ring via GV. The peripheral circuit bit line pattern PBL may correspond to the via upper line pattern GVUP shown in FIG. 3A. A peripheral circuit interlayer structure PIS, a peripheral circuit wiring structure PMS, and a pad structure PDS may be sequentially connected together above the peripheral circuit bit line pattern PBL. The peripheral circuit interlayer structure PIS may include a plurality of peripheral circuit interlayer connection lines PIL, a plurality of peripheral circuit interlayer connection vias PIV, and a peripheral circuit interlayer insulating layer PID. The peripheral circuit interlayer insulating layer PID may cover the peripheral circuit substrate PSUB. The peripheral circuit interlayer insulating layer PID may surround the plurality of peripheral circuit interlayer connection lines PIL, the plurality of peripheral circuit interlayer connection vias PIV, an upper portion of the cell peripheral circuit connection via CPIV, an upper portion of the guard ring via GV, and the peripheral circuit bit line pattern PBL. The plurality of peripheral circuit interlayer connection vias PIV may be connected to any one of the peripheral circuit transistor PTR, the peripheral circuit bit line pattern PBL, and a peripheral circuit interlayer connection line PIL.

The peripheral circuit wiring structure PMS may include a plurality of peripheral circuit wiring connection lines PML, a plurality of peripheral circuit wiring connection vias PMV connected to the plurality of peripheral circuit wiring connection lines PML, and a peripheral circuit wiring insulating layer PMD surrounding the plurality of peripheral circuit wiring connection lines PML and the plurality of peripheral circuit wiring connection vias PMV. In some embodiments, the plurality of peripheral circuit wiring connection lines PML may be buried in an upper portion of the peripheral circuit wiring insulating layer PMD, and the peripheral circuit wiring structure PMS may further include a peripheral circuit wiring protective layer PMP that covers the plurality of peripheral circuit wiring connection lines PML and the peripheral circuit wiring insulating layer PMD. A peripheral circuit wiring connection via PMV located lowermost among the plurality of peripheral circuit wiring connection vias PMV may be connected to a peripheral circuit interlayer connection line PIL located uppermost among the plurality of peripheral circuit interlayer connection lines PIL.

The pad structure PDS may include a plurality of pad patterns PDP and a plurality of pad vias PDV connected to the plurality of pad patterns PDP. A pad via PDV may be connected to a peripheral circuit wiring connection line PML located uppermost among the plurality of peripheral circuit wiring connection lines PML. A cover insulating layer CID may cover the plurality of pad patterns PDP and the plurality of pad vias PDV. In some embodiments, the cover insulating layer CID in the guard ring region GR may cover the upper surface of a pad pattern PDP, and a protective layer PPSL and a photosensitive polyimide (PSPI) layer PSPI may be formed sequentially on the cover insulating layer CID in the guard ring region GR. In some embodiments, the PSPI layer PSPI may not cover a portion of the scribe lane region SL. For example, the PSPI layer PSPI may not cover a portion, other than the scribe guard ring region SGR, of the scribe lane region SL. For example, a portion of the scribe lane region SL may be exposed by the PSPI layer PSPI. In some embodiments, the cover insulating layer CID, the protective layer PPSL, and the PSPI layer PSPI may not be disposed above at least a portion of the upper surface of the pad pattern PDP in the main chip region MCR. In some embodiments, the cover insulating layer CID, the protective layer PPSL, and the PSPI layer PSPI may be formed above the pad pattern PDP in the main chip region MCR, but an outer pad pattern may be formed above the pad pattern PDP such that the upper surface of the outer pad pattern is not at least partially covered by the cover insulating layer CID, the protective layer PPSL, and the PSPI layer PSPI.

The plurality of peripheral circuit interlayer connection lines PIL, the plurality of peripheral circuit interlayer connection vias PIV, the plurality of peripheral circuit wiring connection lines PML, the plurality of peripheral circuit wiring connection vias PMV, and the plurality of pad vias PDV may correspond to the peripheral circuit connection structure PITS shown in FIG. 3A, and the pad pattern PDP located in the guard ring region GR may correspond to the guard upper pattern GSUP shown in FIG. 3A.

The peripheral circuit substrate PSUB may have a deep trench DTR that passes through the peripheral circuit substrate PSUB, and a deep isolation insulating layer DTI may fill the deep trench DTR. Each of a plurality of cell peripheral circuit connection vias CPIV and a plurality of guard ring vias GV may pass through the deep isolation insulating layer DTI that fills the deep trench DTR and may extend toward each of the upper side and the lower side of the peripheral circuit substrate PSUB. Each of the plurality of cell peripheral circuit connection vias CPIV and the plurality of guard ring vias GV may be spaced apart from the peripheral circuit substrate PSUB with a portion of the deep isolation insulating layer DTI therebetween. Each of the plurality of cell peripheral circuit connection vias CPIV and the plurality of guard ring vias GV may pass through the bonding insulating layer BDI. In some embodiments, the plurality of guard ring structures GRS may all pass through one deep isolation insulating layer DTI that fills one deep trench DTR that passes through the peripheral circuit substrate PSUB.

Each of the cell peripheral circuit connection via CPIV and the guard ring via GV may have a tapered shape that extends with a horizontal width decreasing from the upper side to the lower side thereof. For example, each of the cell peripheral circuit connection via CPIV and the guard ring via GV may have a tapered shape that extends with a horizontal width decreasing toward the base substrate BSUB. Each of the deep isolation insulating layer DTI and the deep trench DTR may have a tapered shape that extends with a horizontal width decreasing from the upper side to the lower side thereof. For example, each of the deep isolation insulating layer DTI and the deep trench DTR may have a tapered shape that extends with a horizontal width decreasing toward the base substrate BSUB. For example, the deep trench DTR may have a tapered shape that has a wider portion facing away from the base substrate BSUB, and a narrower portion facing the base substrate BSUB.

A cell landing pattern CLP may be connected to a lower side of each of the cell peripheral circuit connection via CPIV and the guard ring via GV. The cell landing pattern CLP may correspond to the via lower line pattern GVLP shown in FIG. 3A. A cell interlayer structure CIS, a cell intermediate connection structure BIS, and a capacitor connection structure DIS may be sequentially connected together below the cell landing pattern CLP. The cell interlayer structure CIS may include a plurality of cell interlayer connection lines CIL, a plurality of cell interlayer connection vias CIV, and a cell interlayer insulating layer CIDa. The cell interlayer insulating layer CIDa may cover the lower surface of the bonding insulating layer BDI. The cell interlayer insulating layer CIDa may surround the plurality of cell interlayer connection lines CIL, and the plurality of cell interlayer connection vias CIV, a lower portion of the cell peripheral circuit connection via CPIV, a lower portion of the guard ring via GV, and the cell landing pattern CLP. Each of the plurality of cell interlayer connection vias CIV may be connected to at least one of the cell landing pattern CLP, the plurality of cell interlayer connection lines CIL, and a cell bit line BL. For example, the cell interlayer connection via CIV may connect the cell landing pattern CLP to the cell interlayer connection line CIL or connect the cell interlayer connection line CIL to the cell bit line BL. The cell intermediate connection structure BIS may include an intermediate connection line BIL and a cell intermediate insulating layer BID surrounding the intermediate connection line BIL. A cell wiring contact CMC may pass through the cell interlayer insulating layer CIDa and the cell intermediate insulating layer BID and connect any one of the plurality of cell interlayer connection lines CIL to the intermediate connection line BIL. The cell wiring contact CMC may have a tapered shape that extends with a horizontal width decreasing from the upper side to the lower side thereof. For example, the cell wiring contact CMC may have a tapered shape that extends with a horizontal width decreasing toward the base substrate BSUB. The capacitor connection structure DIS may include a plurality of capacitor connection lines DIL, a plurality of capacitor connection vias DIV, and a capacitor cover insulating layer DID. The capacitor cover insulating layer DID may surround the plurality of capacitor connection lines DIL, the plurality of capacitor connection vias DIV, and a capacitor structure CAP. The plurality of capacitor connection vias DIV may connect the capacitor connection line DIL to a capacitor upper electrode TCE and connect the capacitor connection line DIL to the intermediate connection line BIL. A cell protective layer CPSL may be located between the capacitor cover insulating layer DID and the base substrate BSUB. The plurality of cell interlayer connection lines CIL, the plurality of cell interlayer connection vias CIV, the plurality of peripheral circuit wiring connection lines PML, the intermediate connection line BIL, and the plurality of capacitor connection vias DIV may correspond to the cell connection structure CITS shown in FIG. 3A, and the capacitor connection line DIL located in the guard ring region GR may correspond to the guard lower pattern GSLP shown in FIG. 3A.

The memory cell structure MCS may include a plurality of cell bit lines BL, a plurality of channel patterns CHL, a plurality of word lines GL, a plurality of back gate electrodes BG, a plurality of contact plugs CCT, and a plurality of capacitor structures CAP. The plurality of cell bit lines BL may extend lengthwise in a first horizontal direction (an X direction) and may be spaced apart from each other in a second horizontal direction (a Y direction) perpendicular to the first horizontal direction (the X direction). In some embodiments, an insulating capping line BLC may be disposed on each of the plurality of cell bit lines BL. The plurality of channel patterns CHL may be disposed below the plurality of cell bit lines BL, the plurality of contact plugs CCT may be disposed below the plurality of channel patterns CHL, and the plurality of capacitor structures CAP may be disposed below the plurality of contact plugs CCT.

The plurality of channel patterns CHL may be spaced apart from each other in the first horizontal direction (the X direction) and the second horizontal direction (the Y direction) below the plurality of cell bit lines BL. Each of the plurality of contact plugs CCT may be disposed below a corresponding channel pattern CHL among the plurality of channel patterns CHL. Each of the plurality of channel patterns CHL may extend in the vertical direction (the Z direction) between any one selected from among the plurality of cell bit lines BL and any one selected from among the plurality of contact plugs CCT.

In some embodiments, each of the plurality of channel patterns CHL may include a semiconductor material. For example, each of the plurality of channel patterns CHL may include single crystalline silicon, polycrystalline silicon, or amorphous silicon. In some embodiments, each of the plurality of channel patterns CHL may include at least one selected from a group consisting of Ge, SiGe, SiC, GaAs, InAs, and InP. In some embodiments, each of the plurality of channel patterns CHL may include an oxide semiconductor material. Each of the plurality of channel patterns CHL may include at least one of a binary or ternary oxide semiconductor material including a first metal element, a ternary oxide semiconductor material including a first metal element and a second metal element different from each other, and a quaternary oxide semiconductor material including a first metal element, a second metal element, and a third metal element different from each other. The binary or ternary oxide semiconductor material may include, but is not limited to, for example, any one of zinc oxide (ZnO or ZnₓO), gallium oxide (GaO or GaₓO), tin oxide (SnO or SnₓO), zinc oxynitride (ZnON or ZnₓO_{y}N), indium zinc oxide (IZO or InxZn_{y}O), gallium zinc oxide (GZO or GaₓZn_{y}O), tin zinc oxide (TZO or SnₓZn_{y}O), and tin gallium oxide (TGO or SnₓGa_{y}O). The quaternary oxide semiconductor material may include, but is not limited to, for example, indium gallium zinc oxide (IGZO or InₓGa_{Y}Zn_{z}O), indium gallium silicon oxide (IGSO or InₓGa_{y}Si_{z}O), indium tin zinc oxide (ITZO or InₓSn_{Y}Zn_{z}O), indium gallium tin oxide (IGTO or InₓGa_{y}Sn_{z}O), zirconium zinc tin oxide (ZZTO or Zr_{X}Zn_{y}Sn_{z}O), hafnium indium zinc oxide (HIZO or HfₓIn_{Y}Zn_{z}O), gallium zinc tin oxide (GZTO or Ga_{X}Zn_{y}Sn_{z}O), aluminium zinc tin oxide (AZTO or Al_{X}Zn_{y}Sn_{z}O), ytterbium gallium zinc oxide (YGZO or YbₓGa_{Y}Zn_{z}O), and indium aluminum zinc oxide (IAZO).

In some embodiments, each of the plurality of channel patterns CHL may include a crystalline oxide semiconductor material or an amorphous oxide semiconductor material. When each of the plurality of channel patterns CHL includes the crystalline oxide semiconductor material, each of plurality of channel patterns CHL may include at least one of single crystalline, polycrystalline, spinel, and c-axis aligned crystalline (CAAC) characteristics. In some embodiments, each of the plurality of channel patterns CHL may be formed by stacking at least two layers that include a first layer including the crystalline oxide semiconductor material and a second layer including the amorphous oxide semiconductor material. For example, each of the plurality of channel patterns CHL may be formed by sequentially stacking a first layer including the crystalline oxide semiconductor material, a second layer including the amorphous oxide semiconductor material, and a third layer including the crystalline oxide semiconductor material.

According to embodiments, the plurality of contact plugs CCT may be spaced apart from the plurality of cell bit lines BL in the vertical direction (the Z direction) with the plurality of channel patterns CHL therebetween. The plurality of contact plugs CCT may be arranged in a matrix form so as to be spaced apart from each other in the first horizontal direction (the X direction) and the second horizontal direction (the Y direction). The plurality of contact plugs CCT and the plurality of channel patterns CHL may be connected to each other in a one-to-one correspondence.

In some embodiments, the plurality of contact plugs CCT may each include metal, conductive metal nitride, metal silicide, doped polysilicon, or a combination thereof. For example, the plurality of contact plugs CCT may each include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or a combination thereof.

In some embodiments, each of the plurality of contact plugs CCT may include a buried contact BC and a landing pad LP that are sequentially stacked below the plurality of channel patterns CHL. For example, the buried contact BC may include doped polysilicon and the landing pad LP may include metal, but embodiments are not limited thereto. In some embodiments, the landing pad LP and the intermediate connection line BIL may include the same material. In some embodiments, the landing pad LP and the intermediate connection line BIL may be formed together and be at the same vertical level. The cell intermediate insulating layer BID may surround the plurality of contact plugs CCT.

The plurality of back gate electrodes BG and the plurality of word lines GL may be disposed below the plurality of cell bit lines BL. The plurality of back gate electrodes BG and the plurality of word lines GL may each extend lengthwise in the second horizontal direction (the Y direction) between the plurality of cell bit lines BL and the plurality of contact plugs CCT. The plurality of back gate electrodes BG and the plurality of word lines GL may be spaced apart from each other in the first horizontal direction (the X direction). According to embodiments, each of the plurality of channel patterns CHL may be disposed, between one back gate electrode BG and one word line GL adjacent to each other in the first horizontal direction (the X direction), on a corresponding cell bit line BL among the plurality of cell bit lines BL. According to embodiments, the pair of channel patterns CHL may be arranged on opposite sides of each of the plurality of back gate electrodes BG in the first horizontal direction (the X direction), and the pair of word lines GL may be spaced apart from each of the plurality of back gate electrodes BG with the pair of channel patterns CHL therebetween.

In some embodiments, each of the plurality of back gate electrodes BG may include metal, conductive metal nitride, doped polysilicon, or a combination thereof. For example, each of the plurality of back gate electrodes BG may include, but is not limited to, Ti, TiN, Ta, TaN, Mo, Ru, W, WN, TiSiN, WSiN, doped polysilicon, or a combination thereof. Each of the plurality of word lines GL may include metal, conductive metal nitride, or a combination thereof. For example, each of the plurality of word lines GL may include, but is not limited to, Ti, TiN, Ta, TaN, Mo, Ru, W, WN, TiSiN, WSiN, or a combination thereof.

The semiconductor memory device 1 may include a plurality of back gate dielectric layers BGox, which cover both sidewalls of each of the plurality of back gate electrodes BG in the first horizontal direction (the X direction), and a plurality of gate dielectric layers Gox, which are respectively located between the plurality of word lines GL and the plurality of channel patterns CHL adjacent thereto. Each of the plurality of back gate dielectric layers BGox may be located between one back gate electrode BG and one channel pattern CHL adjacent thereto. For example, each of the plurality of back gate dielectric layers BGox may be in contact with the back gate electrode BG and the channel pattern CHL. A pair of gate dielectric layers Gox may be arranged between a pair of channel patterns CHL that are adjacent to each other in the first horizontal direction (the X direction). A pair of word lines GL may be arranged between a pair of gate dielectric layers Gox.

According to embodiments, each of a gate dielectric layer Gox and a back gate dielectric layer BGox may include a silicon oxide layer, a high-k dielectric layer, or a combination thereof. As used herein, the term “high-k dielectric layer” represents a dielectric layer having a higher dielectric constant than silicon oxide. In embodiments, each of the gate dielectric layer Gox and the back gate dielectric layer BGox may include at least one material selected from a group consisting of silicon oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium Silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO). The plurality of back gate electrodes BG, the plurality of word lines GL, the plurality of channel patterns CHL, the plurality of back gate dielectric layers BGox, and the plurality of gate dielectric layers Gox, which are arranged between the plurality of cell bit lines BL and the plurality of contact plugs CCT, may constitute a plurality of VCTs.

The plurality of capacitor structures CAP may be disposed below the plurality of contact plugs CCT and the cell intermediate insulating layer BID. The plurality of capacitor structures CAP may include a plurality of capacitor lower electrodes BCE connected to the plurality of contact plugs CCT, a capacitor dielectric layer DIC conformally covering a surface of each of the plurality of capacitor lower electrodes BCE, and the capacitor upper electrode TCE covering the plurality of capacitor lower electrodes BCE with the capacitor dielectric layer DIC therebetween. Each of the plurality of capacitor lower electrodes BCE may be connected to one channel pattern CHL selected from among the plurality of channel patterns CHL via one contact plug CCT selected from among the plurality of contact plugs CCT. In some embodiments, at least one lower electrode support pattern BES may surround a portion of the plurality of capacitor lower electrodes BCE, and the capacitor dielectric layer DIC may conformally cover the plurality of capacitor lower electrodes BCE and the at least one lower electrode support pattern BES. In some embodiments, at least two lower electrode support patterns BES at different vertical levels may surround another portion of the plurality of capacitor lower electrodes BCE at different vertical levels.

Each of the capacitor lower electrodes BCE may have, but is not limited to, a solid column shape with a circular horizontal cross-section, i.e., a pillar shape. In some embodiments, each of the plurality of capacitor lower electrodes BCE may have a cylindrical shape with a closed bottom. In some embodiments, the plurality of capacitor lower electrodes BCE may be arranged in a line in each of the first horizontal direction (the X direction) and the second horizontal direction (the Y direction), thereby forming a matrix pattern. In some embodiments, the plurality of capacitor lower electrodes BCE may be arranged in a zigzag pattern in the first horizontal direction (the X direction) or the second horizontal direction (the Y direction), thereby forming a honeycomb shape. The plurality of capacitor lower electrodes BCE may include, for example, impurity-doped silicon, a metal such as tungsten and copper, or a conductive metal compound such as titanium nitride.

The capacitor dielectric layer DIC may conformally cover the surfaces of the plurality of capacitor lower electrodes BCE. In some embodiments, the capacitor dielectric layer DIC may include a high-k dielectric layer. In some embodiments, the capacitor dielectric layer DIC may include metal oxide including at least one metal selected from a group consisting of hafnium (Hf), zirconium (Zr), aluminum (Al), niobium (Nb), cerium (Ce), lanthanum (La), tantalum (Ta), and titanium (Ti). In some embodiments, each of the plurality of capacitor lower electrodes BCE and the capacitor upper electrode TCE may include metal, conductive metal oxide, conductive metal nitride, conductive metal oxynitride, or a combination thereof. In some embodiments, each of the plurality of capacitor lower electrodes BCE and the capacitor upper electrode TCE may include Nb, Nb oxide, Nb nitride, Nb oxynitride, Ti, Ti oxide, Ti nitride, Ti oxynitride, Co, Co oxide, Co nitride, Co oxynitride, Sn, Sn oxide, Sn nitride, Sn oxynitride, or a combination thereof. In some embodiments, each of the plurality of capacitor lower electrodes BCE and the capacitor upper electrode TCE may include TaN, TiAlN, TaAlN, V, VN, Mo, MoN, W, WN, Ru, RuO₂, SrRuO₃, Ir, IrO₂, Pt, PtO, SRO(SrRuO₃), BSRO((Ba,Sr)RuO₃), CRO(CaRuO₃), LSCO((La,Sr)CoO₃), or a combination thereof. However, the constituent material of each of the plurality of capacitor lower electrodes BCE and the capacitor upper electrode TCE is not limited to the above examples. In some embodiments, the capacitor upper electrode TCE may further include at least one of a doped semiconductor material layer and an interface layer in addition to the metal material and may have a stack structure thereof. The doped semiconductor material layer may include, for example, at least one of doped polysilicon and doped polycrystalline silicon germanium (poly-SiGe). The interface layer may include a metal material. The interface layer may include, for example, at least one of metal oxide, metal nitride, metal carbide, and metal silicide.

The memory cell structure MCS shown in FIG. 3A may have a shape corresponding to that of the memory cell structure MCS shown in FIG. 4B, and the peripheral circuit structure PCRT shown in FIG. 3A may have a shape corresponding to that of the peripheral circuit structure PCRT shown in FIG. 4B. The memory cell structure MCS shown in FIG. 3B may have a shape corresponding to the inverted shape of the memory cell structure MCS shown in FIG. 4B, and the peripheral circuit structure PCRT shown in FIG. 3B may have a shape corresponding to the inverted shape of the peripheral circuit structure PCRT shown in FIG. 4B. For example, the plurality of peripheral circuit transistors PTR may be disposed on the lower surface of the peripheral circuit substrate PSUB shown in FIG. 3B. The memory cell structure MCS shown in FIG. 3C may have a shape corresponding to the shape of the memory cell structure MCS shown in FIG. 4B, and the peripheral circuit structure PCRT shown in FIG. 3C may have a shape corresponding to the inverted shape of the peripheral circuit structure PCRT shown in FIG. 4B. The memory cell structure MCS shown in FIG. 3D may have a shape corresponding to the shape of the memory cell structure MCS shown in FIG. 4B or the inverted shape of the memory cell structure MCS, and the peripheral circuit structure PCRT shown in FIG. 3D may have a shape corresponding to the shape of the peripheral circuit structure PCRT shown in FIG. 4B.

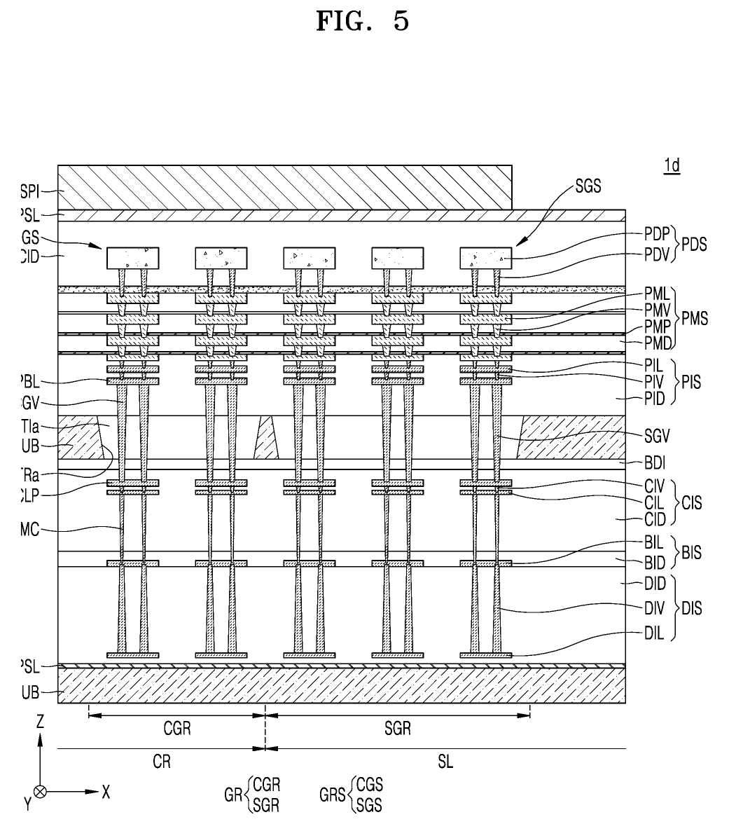

FIG. 5 is a cross-sectional view illustrating a semiconductor memory device 1d according to embodiments.

Referring to FIG. 5, the semiconductor memory device 1d may include a chip region CR defined by a scribe lane region SL. The chip region CR and the scribe lane region SL may include a chip guard ring region CGR and a scribe guard ring region SGR, respectively, which are adjacent to each other. The chip region CR may include a main chip region MCR (FIG. 4B) and the chip guard ring region CGR.

The semiconductor memory device 1d includes a base substrate BSUB, a memory cell structure MCS above the base substrate BSUB, and a peripheral circuit structure PCRT above the memory cell structure MCS. The semiconductor memory device 1d may further include a plurality of guard ring structures GRS above the base substrate BSUB. The plurality of guard ring structures GRS may include at least one chip guard ring structure CGS and at least one scribe guard ring structure SGS.

The peripheral circuit substrate PSUB may have at least two deep trenches DTRa that pass through the peripheral circuit substrate PSUB, and at least two deep isolation insulating layers DTIa may fill the at least two deep trenches DTRa. The at least two deep trenches DTRa and the at least two deep isolation insulating layers DTIa filling the at least two deep trenches DTRa may be spaced apart from each other in a horizontal direction. In some embodiments, the at least one chip guard ring structure CGS and the at least one scribe guard ring structure SGS may pass through different deep isolation insulating layers DTIa that fill different deep trenches DTRa, among the at least two deep isolation insulating layers DTIa that fill the at least two deep trenches DTRa that pass through the peripheral circuit substrate PSUB.

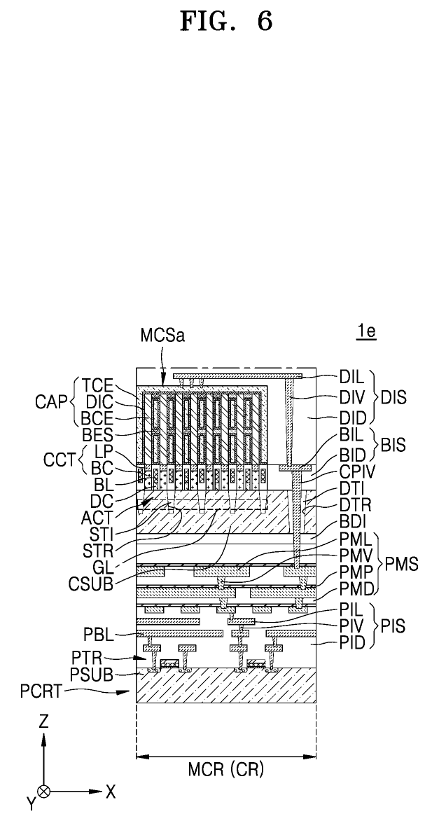

FIG. 6 is a cross-sectional view illustrating a semiconductor memory device 1e according to embodiments. In the description of FIG. 6, repeated descriptions may be omitted.

Referring to FIG. 6, the semiconductor memory device 1e includes a peripheral circuit structure PCRT and a memory cell structure MCSa above the peripheral circuit structure PCRT. In some embodiments, the semiconductor memory device 1e may have a CoP structure in which the memory cell structure MCSa and the peripheral circuit structure PCRT overlap each other in a vertical direction (a Z direction). The memory cell structure MCSa may include a plurality of memory cells. FIG. 6 illustrates an example in which the semiconductor memory device 1e includes the memory cell structure MCSa including a BCAT DRAM, but embodiments are not limited thereto. For example, the semiconductor memory device 1e may include an inverted shape of the memory cell structure MCS shown in FIG. 4B instead of the memory cell structure MCSa shown in FIG. 6. The memory cell structure MCSa may include a cell substrate CSUB. The peripheral circuit structure PCRT may include a peripheral circuit substrate PSUB and a plurality of peripheral circuit transistors PTR. The peripheral circuit substrate PSUB may be located on the lower side of the peripheral circuit structure PCRT. A bonding insulating layer BDI may be formed on the lower surface of the cell substrate CSUB. The memory cell structure MCSa may be bonded to the peripheral circuit structure PCRT via the bonding insulating layer BDI. The memory cell structure MCSa may be electrically connected to the peripheral circuit structure PCRT through a cell peripheral circuit connection via CPIV. The peripheral circuit substrate PSUB may be referred to as a support substrate, and the cell substrate CSUB may be referred to as an intermediate substrate. Each of the cell substrate CSUB and the peripheral circuit substrate PSUB may include, for example, semiconductor materials, such as a group IV semiconductor material, a group III-V semiconductor material or a group II-VI semiconductor material, and a group II-VI oxide semiconductor material.

The peripheral circuit structure PCRT may include the peripheral circuit substrate PSUB, the plurality of peripheral circuit transistors PTR, a peripheral circuit bit line pattern PBL, a peripheral circuit interlayer structure PIS, and a peripheral circuit wiring structure PMS.

The memory cell structure MCS may include a plurality of active regions ACT defined by an element isolation layer STI filling an element isolation trench STR formed in the cell substrate CSUB, a plurality of word lines GL across the plurality of active regions ACT, a plurality of cell bit lines BL on the cell substrate CSUB, a plurality of direct contacts DC connecting the plurality of cell bit lines BL to the plurality of active regions ACT, a plurality of contact plugs CCT connected to the plurality of active regions ACT and extending between the plurality of cell bit lines BL, and a plurality of capacitor structures CAP on the plurality of contact plugs CCT. The memory cell structure MCS may further include a cell intermediate connection structure BIS and a capacitor connection structure DIS. The plurality of word lines GL may extend parallel to each other in a first horizontal direction (an X direction) across the plurality of active regions ACT. A plurality of gate dielectric layers may be arranged between the plurality of active regions ACT and the plurality of word lines GL. The plurality of cell bit lines BL may extend parallel to each other in a second horizontal direction (a Y direction) intersecting the first horizontal direction (the X direction). Each of the plurality of contact plugs CCT may include a buried contact BC and a landing pad LP that are sequentially stacked on the plurality of active regions ACT. The plurality of capacitor structures CAP may include a plurality of capacitor lower electrodes BCE connected to the plurality of contact plugs CCT, a capacitor dielectric layer DIC conformally covering a surface of each of the plurality of capacitor lower electrodes BCE, and a capacitor upper electrode TCE covering the plurality of capacitor lower electrodes BCE with the capacitor dielectric layer DIC therebetween. In some embodiments, at least one lower electrode support pattern BES may surround a portion of the plurality of capacitor lower electrodes BCE, and the capacitor dielectric layer DIC may conformally cover the plurality of capacitor lower electrodes BCE and the at least one lower electrode support pattern BES.

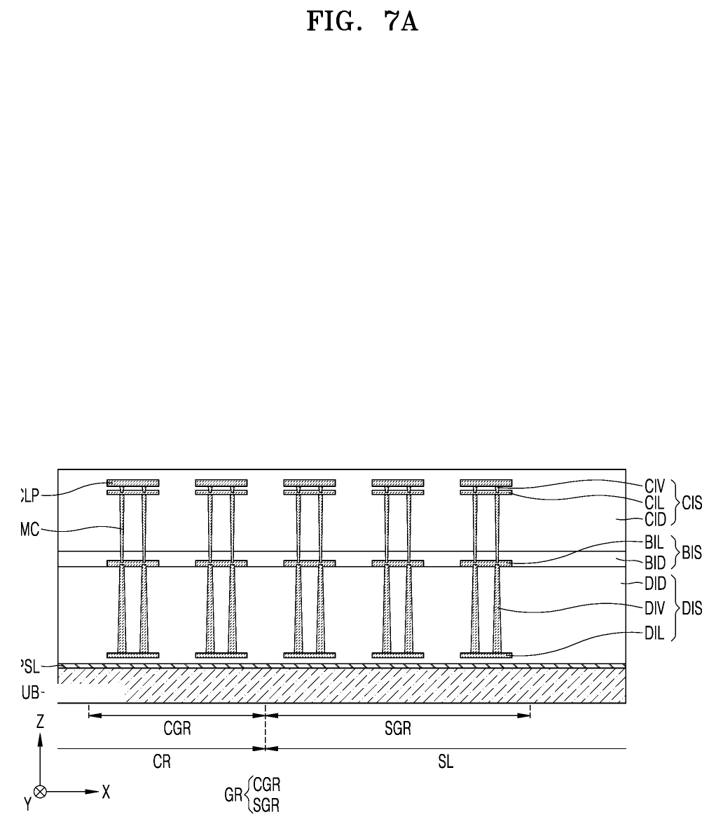

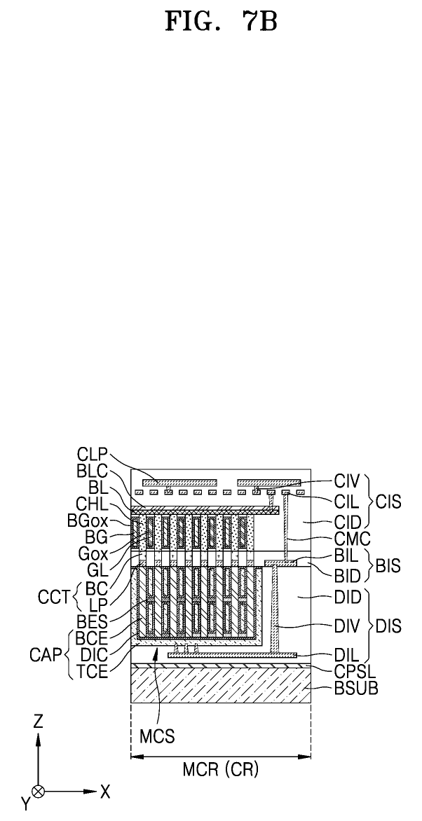

FIGS. 7A and 7B, FIGS. 8A and 8B, and FIGS. 9A and 9B are cross-sectional views illustrating a method of manufacturing a semiconductor memory device, according to embodiments. In the descriptions of FIGS. 7A and 7B, FIGS. 8A and 8B, and FIGS. 9A and 9B, repeated descriptions may be omitted.

Referring to FIGS. 7A and 7B together, a memory cell structure MCS is formed, and then the memory cell structure MCS is attached to a base substrate BSUB such that a capacitor structure CAP faces the base substrate BSUB. A cell protective layer CPSL may be located between the memory cell structure MCS and the base substrate BSUB. The memory cell structure MCS includes a plurality of memory cells including a plurality of cell bit lines BL, a plurality of channel patterns CHL, a plurality of word lines GL, a plurality of gate dielectric layers Gox, a plurality of back gate electrodes BG, a plurality of back gate dielectric layers BGox, a plurality of contact plugs CCT, and a plurality of capacitor structures CAP, a capacitor connection structure DIS, a cell intermediate connection structure BIS, a cell interlayer structure CIS, a cell wiring contact CMC, and a cell landing pattern CLP.

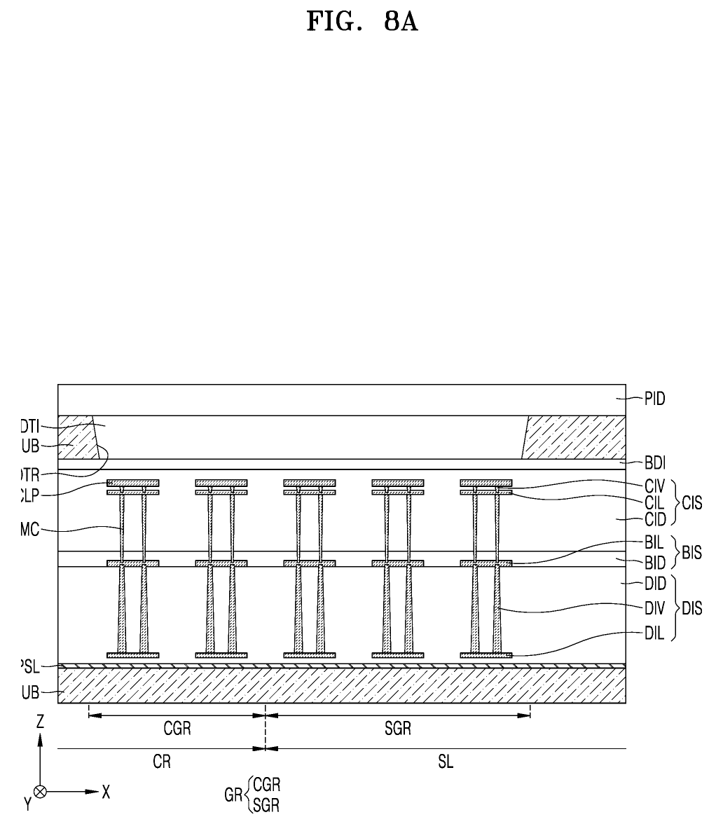

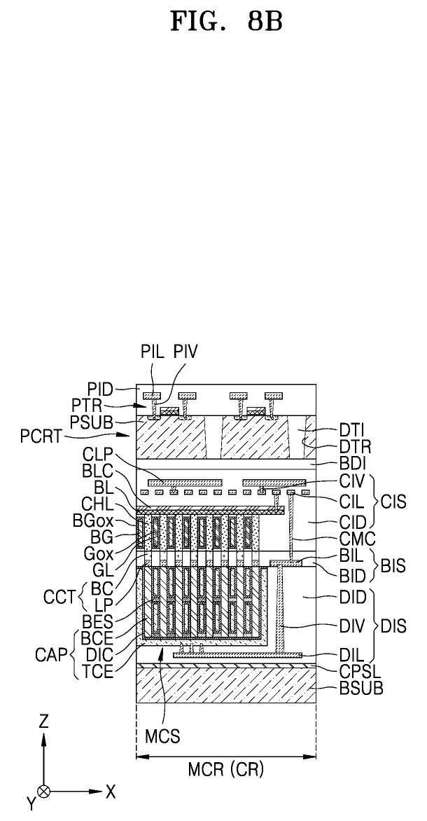

Referring to FIGS. 8A and 8B together, a peripheral circuit substrate PSUB having a plurality of peripheral circuit transistors PTR formed thereon is attached to the memory cell structure MCS. A bonding insulating layer BDI may be formed on the lower surface of the peripheral circuit substrate PSUB, and the peripheral circuit substrate PSUB may be bonded to the memory cell structure MCS via the bonding insulating layer BDI. A cover insulating layer CID of the memory cell structure MCS may be covalently bonded to the bonding insulating layer BDI, and thus, the memory cell structure MCS may be bonded to the peripheral circuit structure PCRT.

The peripheral circuit substrate PSUB may have a deep trench DTR that passes through the peripheral circuit substrate PSUB, and a deep isolation insulating layer DTI may fill the deep trench DTR. Each of the deep isolation insulating layer DTI and the deep trench DTR may be formed in a tapered shape that extends with a horizontal width decreasing from the upper side to the lower side thereof. For example, each of the deep isolation insulating layer DTI and the deep trench DTR may be formed in a tapered shape that extends with a horizontal width decreasing toward the base substrate BSUB.

Above the peripheral circuit substrate PSUB, there may be formed a peripheral circuit interlayer connection line PIL, a peripheral circuit interlayer connection via PIV connecting the peripheral circuit interlayer connection line PIL to a peripheral circuit transistor PTR, and a peripheral circuit interlayer insulating layer PID that covers the plurality of peripheral circuit transistors PTR and surrounds the peripheral circuit interlayer connection line PIL and the peripheral circuit transistor PTR. The peripheral circuit interlayer connection line PIL, the peripheral circuit interlayer connection via PIV, and a plurality of peripheral circuit interlayer insulating layers PID shown in FIGS. 8A and 8B may respectively and at least partially correspond to the plurality of peripheral circuit interlayer connection lines PIL, the plurality of peripheral circuit interlayer connection vias PIV, and the peripheral circuit interlayer insulating layer PID in the peripheral circuit interlayer structure PIS shown in FIGS. 4A and 4B.

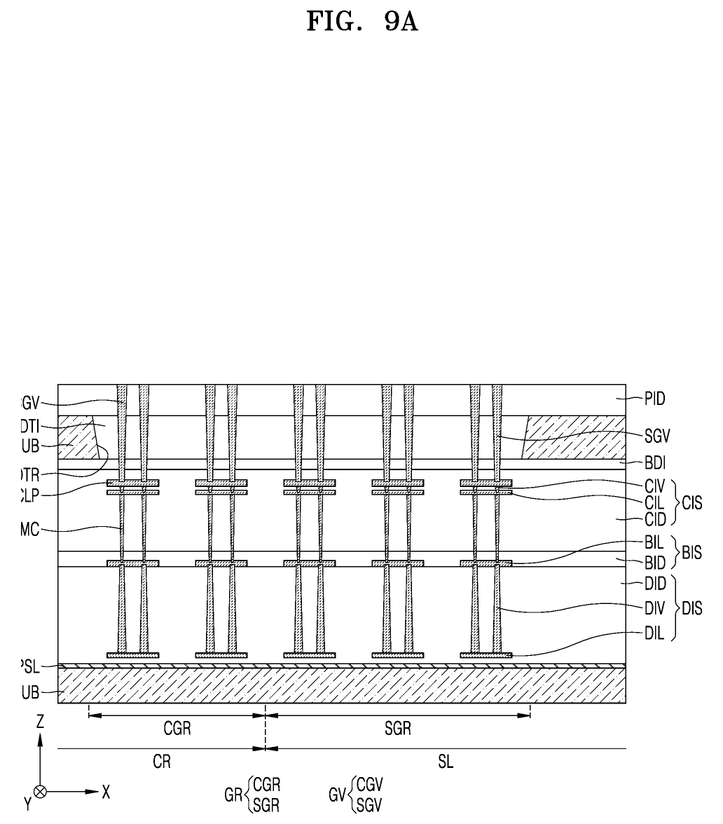

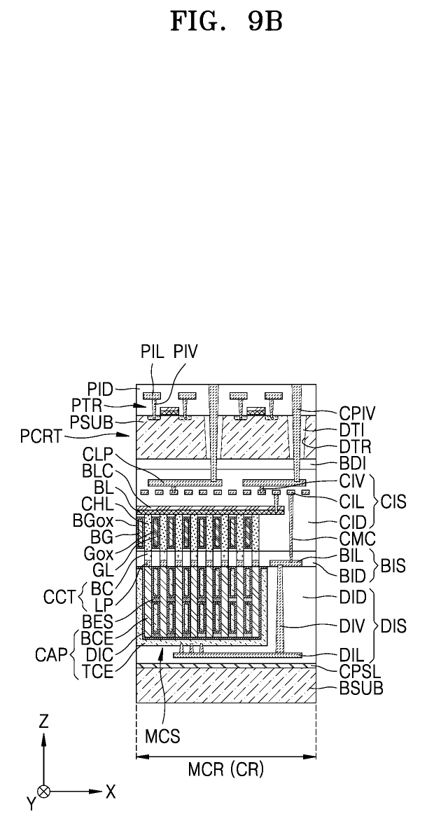

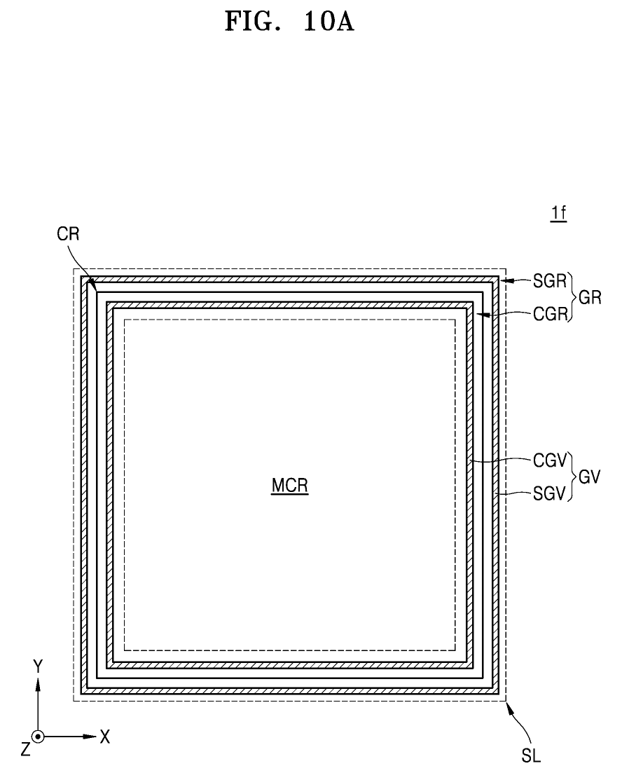

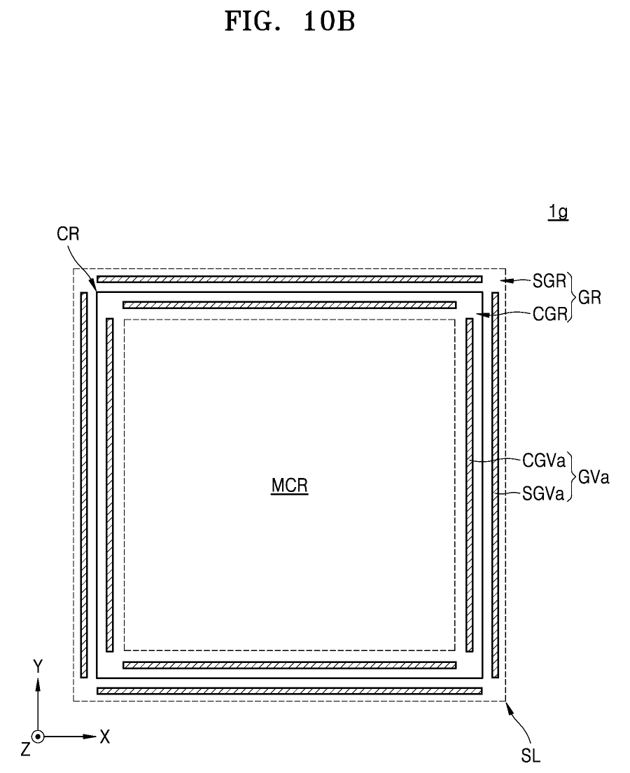

Referring to FIGS. 9A and 9B together, there are formed a cell peripheral circuit connection via CPIV and a plurality of guard ring vias GV that are connected to a cell landing pattern CLP via a peripheral circuit interlayer insulating layer PID, a deep isolation insulating layer DTI, a bonding insulating layer BDI, and a cover insulating layer CID. A guard ring via GV may include a chip guard ring via CGV located in a chip guard ring region CGR and a scribe guard ring via SGV located in a scribe guard ring region SGR. Each of the cell peripheral circuit connection via CPIV and the plurality of guard ring vias GV may be formed in a tapered shape that extends with a horizontal width decreasing from the upper side to the lower side thereof. For example, each of the cell peripheral circuit connection via CPIV and the plurality of guard ring vias GV may be formed in a tapered shape that extends with a horizontal width decreasing toward the base substrate BSUB.

Subsequently, with reference to FIGS. 4A and 4B, the peripheral circuit bit line pattern PBL, the peripheral circuit interlayer structure PIS, the peripheral circuit wiring structure PMS, and the pad structure PDS may be formed, and thus, the semiconductor memory device 1 may be formed that includes the guard ring structure GRS including the chip guard ring structure CGS and the scribe guard ring structure SGS.

FIGS. 10A and 10B are plan layouts illustrating semiconductor memory devices 1f and 1g, respectively, according to embodiments.

Referring to FIG. 10A, the semiconductor memory device 1f may include a chip region CR and a portion of a scribe lane region SL adjacent to the chip region CR. A guard ring region GR may extend along a boundary between each of a plurality of chip regions CR and the scribe lane region SL. The guard ring region GR may include a chip guard ring region CGR and a scribe guard ring region SGR. The chip region CR may include a main chip region MCR and the chip guard ring region CGR surrounding the main chip region MCR.

A plurality of guard ring vias GV may be arranged in the guard ring region GR. The plurality of guard ring vias GV may include at least one chip guard ring via CGV located in the chip guard ring region CGR and at least one scribe guard ring via SGV located in the scribe guard ring region SGR. The chip guard ring vias CGV and the scribe guard ring vias SGV may be spaced apart from each other.

The chip guard ring via CGV and the scribe guard ring via SGV may extend, along the boundary between the chip region CR and the scribe lane region SL, in the chip guard ring region CGR and the scribe guard ring region SGR, respectively. In some embodiments, the chip guard ring via CGV may have a planar shape of a quadrangular ring that continuously extends to completely surround the main chip region MCR, and the scribe guard ring via SGV may have a planar shape of a quadrangular ring that continuously extends to completely surround the chip region CR. The chip guard ring vias CGV may be between the scribe guard ring vias SGV and the main chip region MCR.

Referring to FIG. 10B, the semiconductor memory device 1g may include a chip region CR and a portion of a scribe lane region SL adjacent to the chip region CR. A guard ring region GR may extend along a boundary between each of a plurality of chip regions CR and the scribe lane region SL. The guard ring region GR may include a chip guard ring region CGR and a scribe guard ring region SGR. The chip region CR may include a main chip region MCR and the chip guard ring region CGR surrounding the main chip region MCR.

A plurality of guard ring vias GVa may be arranged in the guard ring region GR. The plurality of guard ring vias GVa may include a plurality of chip guard ring vias CGVa located in the chip guard ring region CGR and a plurality of scribe guard ring vias SGVa located in the scribe guard ring region SGR. The chip guard ring vias CGVa and the scribe guard ring vias SGVa may be spaced apart from each other.

The plurality of chip guard ring vias CGVa may extend along the boundary between the chip region CR and the scribe lane region SL in the chip guard ring region CGR and may be spaced apart from each other. The plurality of scribe guard ring vias SGVa may extend along the boundary between the chip region CR and the scribe lane region SL in the scribe guard ring region SGR and may be spaced apart from each other. For example, the plurality of chip guard ring vias CGVa may surround the main chip region MCR, and may be spaced apart from each other so as not to completely surround the main chip region MCR. For example, the plurality of scribe guard ring vias SGVa may surround the chip region CR, and may be spaced apart from each other so as not to completely surround the chip region CR.

FIG. 10B illustrates that the plurality of chip guard ring vias CGVa and the plurality of scribe guard ring vias SGVa each have the planar shape of a straight bar and are spaced apart from each other around vertices of the boundary between the chip region CR and the scribe lane region SL, but embodiments are not limited thereto. For example, some of the plurality of chip guard ring vias CGVa and the plurality of scribe guard ring vias SGVa may have an L-shape that extends across the vertex of the boundary between the chip region CR and the scribe lane region SL. For example, at least two of the plurality of chip guard ring vias CGVa may be spaced apart from each other at side regions of the boundary between the chip region CR and the scribe lane region SL. For example, at least two of the plurality of scribe guard ring vias SGVa may be spaced apart from each other at side regions of the boundary between the chip region CR and the scribe lane region SL.

While aspects of embodiments have been particularly shown and described, it will be understood that various changes in form and details may be made therein without departing from the spirit and scope of the following claims.

What is claimed is:

1. A semiconductor memory device having a main chip region and a guard ring region surrounding the main chip region, the semiconductor memory device comprising:
a support substrate;
a memory cell structure above the support substrate, the memory cell structure comprising a plurality of memory cells in the main chip region;
a peripheral circuit structure above the support substrate such that the peripheral circuit structure and the memory cell structure are stacked along a vertical direction, the peripheral circuit structure comprising a plurality of peripheral circuit transistors in the main chip region;
an intermediate substrate located between the memory cell structure and the peripheral circuit structure;
a deep isolation insulating layer in a deep trench passing through the intermediate substrate; and
a guard ring structure comprising a guard ring via in the guard ring region, wherein the guard ring structure passes through the deep isolation insulating layer and extends beyond an upper surface of the intermediate substrate and beyond a lower surface of the intermediate substrate.

2. The semiconductor memory device of claim 1, wherein the guard ring via has a tapered shape with a horizontal width that decreases toward the support substrate.

3. The semiconductor memory device of claim 2, wherein the guard ring via is formed as a single body that extends from an uppermost end to a lowermost end of the guard ring via.

4. The semiconductor memory device of claim 2, wherein the guard ring via has a linear and planar shape extending along the guard ring region.

5. The semiconductor memory device of claim 2, wherein the guard ring via has a planar shape of a quadrangular ring surrounding the main chip region.

6. The semiconductor memory device of claim 1, further comprising a bonding insulating layer between the memory cell structure and the intermediate substrate,
wherein the memory cell structure and the peripheral circuit structure are sequentially stacked above the support substrate along the vertical direction, and
wherein the guard ring via passes through the deep isolation insulating layer and the bonding insulating layer along the vertical direction.

7. The semiconductor memory device of claim 6, wherein the plurality of peripheral circuit transistors are on the upper surface of the intermediate substrate.

8. The semiconductor memory device of claim 7, wherein each of the deep trench and the deep isolation insulating layer has a tapered shape extending with a horizontal width that decreases toward the support substrate.

9. The semiconductor memory device of claim 6, wherein the memory cell structure comprises a vertical channel transistor (VCT) dynamic random-access memory (DRAM), and
wherein the VCT DRAM comprises a cell bit line, a word line and a back gate electrode below the cell bit line, a channel pattern between the word line and the back gate electrode below the cell bit line, a contact plug below the channel pattern, and a capacitor structure below the contact plug.

10. The semiconductor memory device of claim 1, wherein the peripheral circuit structure and the memory cell structure are sequentially stacked above the support substrate along the vertical direction,
wherein the guard ring via has a tapered shape extending with a horizontal width that decreases toward the support substrate, and
wherein each of the deep trench and the deep isolation insulating layer has a tapered shape extending with a horizontal width that increases toward the support substrate.

11. A semiconductor memory device having a main chip region and a guard ring region, wherein the guard ring region comprises a chip guard ring region surrounding the main chip region and a scribe guard ring region surrounding the chip guard ring region, the semiconductor memory device comprising:
a base substrate;
a memory cell structure above the base substrate and comprising a plurality of memory cells in the main chip region;
a peripheral circuit structure above the memory cell structure, and comprising a peripheral circuit substrate located on a lower side of the peripheral circuit structure facing the memory cell structure and a plurality of peripheral circuit transistors on an upper surface of the peripheral circuit substrate in the main chip region;
a deep isolation insulating layer in a deep trench passing through the peripheral circuit substrate; and
a plurality of guard ring structures comprising a chip guard ring structure and a scribe guard ring structure, wherein the chip guard ring structure passes through the deep isolation insulating layer in the chip guard ring region and extends beyond the upper surface of the peripheral circuit substrate and beyond a lower surface of the peripheral circuit substrate, and wherein the scribe guard ring structure passes through the deep isolation insulating layer in the scribe guard ring region beyond the upper surface of the peripheral circuit substrate beyond the lower surface of the peripheral circuit substrate,
wherein each of the plurality of guard ring structures comprises a guard ring via having a tapered shape extending with a horizontal width that decreases toward the base substrate, and wherein each of the plurality of guard ring structures passes through the deep isolation insulating layer.

12. The semiconductor memory device of claim 11, wherein the guard ring via in each of the plurality of guard ring structures extends from a vertical level which is between an uppermost end of each of the plurality of guard ring structures and the upper surface of the peripheral circuit substrate, to a vertical level which is between a lowermost end of each of the plurality of guard ring structures and the lower surface of the peripheral circuit substrate.

13. The semiconductor memory device of claim 11, wherein a number of scribe guard ring structures arranged in the scribe guard ring region is at least two and greater than a number of chip guard ring structures.

14. The semiconductor memory device of claim 11, wherein the guard ring via in each of the plurality of guard ring structures has a linear and planar shape extending along a boundary between the chip guard ring region and the scribe guard ring region.

15. The semiconductor memory device of claim 14, wherein each of the plurality of guard ring structures comprises a plurality of guard ring vias,
wherein the plurality of guard ring vias respectively provided in the plurality of guard ring structures extend along a same direction as the boundary between the chip guard ring region and the scribe guard ring region, and
wherein the plurality of guard ring vias are spaced apart from each other along a direction perpendicular to the boundary between the chip guard ring region and the scribe guard ring region.

16. The semiconductor memory device of claim 11, wherein the memory cell structure comprises:
a capacitor structure above the base substrate;
a contact plug above the capacitor structure;
a channel pattern above the contact plug;
a word line and a back gate electrode arranged on opposite sides of the channel pattern; and
a cell bit line above the channel pattern, the word line, and the back gate electrode.

17. The semiconductor memory device of claim 11, wherein the guard ring via in each of the plurality of guard ring structures has a planar shape of a quadrangular ring extending continuously and surrounding the main chip region.

18. A semiconductor memory device having a main chip region and a guard ring region, wherein the guard ring region comprises a chip guard ring region surrounding the main chip region and a scribe guard ring region surrounding the chip guard ring region, the semiconductor memory device comprising:
a base substrate;
a memory cell structure above the base substrate and comprising a plurality of memory cells in the main chip region;
a peripheral circuit structure above the memory cell structure, the peripheral circuit structure comprising a peripheral circuit substrate located on a lower side of the peripheral circuit structure facing the memory cell structure, and a plurality of peripheral circuit transistors on an upper surface of the peripheral circuit substrate in the main chip region;
a bonding insulating layer between the memory cell structure and a lower surface of the peripheral circuit substrate;
a deep isolation insulating layer in a deep trench defined by the peripheral circuit substrate, the deep trench having a tapered shape extending with a horizontal width that decreases toward the base substrate; and
a plurality of guard ring structures comprising a chip guard ring structure and a scribe guard ring structure, wherein the chip guard ring structure passes through the deep isolation insulating layer and the bonding insulating layer in the chip guard ring region and extends beyond the upper surface of the peripheral circuit substrate and beyond the lower surface of the peripheral circuit substrate, and the scribe guard ring structure passes through the deep isolation insulating layer and the bonding insulating layer in the scribe guard ring region and extends beyond the upper surface of the peripheral circuit substrate and beyond the lower surface of the peripheral circuit substrate,
wherein each of the plurality of guard ring structures comprises a guard ring via having a tapered shape extending with a horizontal width that decreases toward the base substrate,
wherein the memory cell structure comprises:
a capacitor structure comprising a capacitor lower electrode above the base substrate, a capacitor dielectric layer covering the capacitor lower electrode, and a capacitor upper electrode covering the capacitor lower electrode with the capacitor dielectric layer therebetween;
a contact plug connected to the capacitor lower electrode above the capacitor structure;
a channel pattern connected to the contact plug above the contact plug;
a word line and a back gate electrode arranged on opposite sides of the channel pattern;
a gate dielectric layer located between the channel pattern and the word line;
a back gate dielectric layer located between the channel pattern and the back gate electrode; and
a cell bit line connected to the channel pattern above the channel pattern, the word line, and the back gate electrode, and
wherein the guard ring via in each of the plurality of guard ring structures has a linear and planar shape extending along a boundary between the chip guard ring region and the scribe guard ring region.

19. The semiconductor memory device of claim 18, wherein each of the plurality of guard ring structures comprises a metal, and
wherein the guard ring via in each of the plurality of guard ring structures is formed as a single body that extends from an uppermost end to a lowermost end of the guard ring via.

20. The semiconductor memory device of claim 18, further comprising a cell peripheral circuit connection via passing through the deep isolation insulating layer in the main chip region to connect the memory cell structure to the peripheral circuit structure,
wherein the cell peripheral circuit connection via has a tapered shape extending with a horizontal width that decreases toward the base substrate, and
wherein the cell peripheral circuit connection via and the guard ring via are at a same vertical level.
